(19) United States
(12) Patent Application Publication
(10) Pub. No.: US 2025/0129507 A1
(43) Pub. Date: Apr. 24, 2025

(54) METHODS AND SYSTEMS FOR CONTROLLING CRYSTAL GROWTH

(71) Applicant: MEISHAN BOYA ADVANCED MATERIALS CO., LTD., Meishan (CN)

(72) Inventors: Yu WANG, Meishan (CN); Weiming GUAN, Meishan (CN); Zhenxing LIANG, Meishan (CN)

(73) Assignee: MEISHAN BOYA ADVANCED MATERIALS CO., LTD., Meishan (CN)

(21) Appl. No.: 19/001,383

(22) Filed: Dec. 24, 2024

Related U.S. Application Data
(63) Continuation-in-part of application No. 17/227,256, filed on Apr. 9, 2021, now Pat. No. 12,188,146.
Application No. 17/227,256 is a continuation of application No. PCT/CN2021/071114, filed on Jan. 11, 2021.
(63) Continuation-in-part of application No. PCT/CN2024/076441, filed on Feb. 6, 2024.

(51) Int. Cl. C30B 15/28; C30B 15/20

(52) U.S. Cl. CPC C30B 15/28; C30B 15/206

(57) ABSTRACT

The embodiments of the present disclosure disclose a method for controlling crystal growth. The method includes: obtaining an actual crystal parameter in a target time slice; obtaining a reference crystal parameter in the target time slice; determining a temperature control parameter based on the actual crystal parameter and the reference crystal parameter; determining a pulling control parameter based on the actual crystal parameter and the reference crystal parameter; and adjusting a temperature and a pulling speed in a next time slice after the target time slice respectively based on the temperature control parameter and the pulling control parameter.

### CROSS-REFERENCE TO RELATED APPLICATIONS

This application is a continuation-in-part of U.S. application Ser. No. 17/227,256, filed on Apr. 9, 2021, which is a Continuation of International Application No. PCT/CN2021/071114, filed on Jan. 11, 2021; this application is a continuation-in-part of International Application No. PCT/CN2024/076441, filed on Feb. 6, 2024. Each of the above-referenced applications is hereby incorporated by reference.

### TECHNICAL FIELD

The present disclosure generally relates to the technical field of crystal preparation, and in particular, to methods and systems for controlling crystal growth.

### BACKGROUND

In a process of crystal preparation, a process condition and a control parameter may determine a quality of crystal to be prepared to a certain extent. Further, the quality of the crystal may also affect a performance of a device prepared using the crystal. If it is desired to prepare a crystal with a high-quality, various process conditions and control parameters in the crystal growth need to be accurately controlled during the process of crystal preparation. Therefore, it is desirable to provide methods and systems for controlling crystal growth to achieve accurate and efficient control of the crystal growth process.

### SUMMARY

One embodiment of the present disclosure provides a method for controlling crystal growth. The method may include obtaining an actual crystal parameter in a target time slice, wherein the actual crystal parameter may include at least one of an actual crystal mass, an actual crystal diameter, an actual crystal height, or an actual crystal shape. The method may include obtaining a reference crystal parameter in the target time slice, wherein the reference crystal parameter may include at least one of a reference crystal mass, a reference crystal diameter, a reference crystal height, or a reference crystal shape. The method may also include determining a temperature control parameter based on the actual crystal parameter and the reference crystal parameter. The method may include determining a pulling control parameter based on the actual crystal parameter and the reference crystal parameter. The method may further include adjusting a temperature and a pulling speed in a next time slice after the target time slice respectively based on the temperature control parameter and the pulling control parameter.

In some embodiments, the obtaining an actual crystal parameter in a target time slice may include: determining a drop height of a liquid level in the target time slice, based on the actual crystal mass, a density of a raw material under a molten state, and a size of a chamber; determining the actual crystal height based on a pulling height and the drop height of the liquid level in the target time slice; and determining the actual crystal diameter based on the actual crystal mass and the actual crystal height.

In some embodiments, the obtaining a reference crystal parameter in the target time slice may include: constructing a crystal growth model based on at least one of a preset crystal parameter or a preset crystal growth parameter; and determining, based on the crystal growth model, the reference crystal parameter corresponding to the target time slice.

In some embodiments, the preset crystal parameter may include at least one of a crystal type, a preset crystal density, a preset crystal mass, a preset seed crystal height, a preset seed crystal diameter, a preset shoulder height, a preset height at an equal diameter, a preset diameter at the equal diameter, a preset tail height, a preset crystal tail height, a preset crystal tail diameter, a preset shoulder angle, a preset tail angle, or a ratio of a transition angel between the seed crystal and a shoulder front end to a transition angel between a shoulder end and a front end at the equal diameter.

In some embodiments, the preset crystal growth parameter may include at least one of a preset crystal growth speed or a preset growth coefficient.

In some embodiments, the constructing a crystal growth model based on the preset crystal parameter may include: constructing the crystal growth model based on the preset crystal parameter according to a three-dimensional modeling manner.

In some embodiments, the determining a temperature control parameter based on the actual crystal parameter and the reference crystal parameter may include: determining a difference between the actual crystal parameter and the reference crystal parameter; and determining the temperature control parameter based on the difference and a reference crystal growth parameter.

In some embodiments, the determining a pulling control parameter based on the actual crystal parameter and the reference crystal parameter may include: determining a drop speed of a liquid level in the target time slice based on the actual crystal mass, a melting density of a raw material, and a size of a chamber; and determining the pulling control parameter based on the drop speed of the liquid level and a reference crystal growth parameter.

In some embodiments, before the obtaining an actual crystal parameter in a target time slice, the method may further include: heating a chamber to a preset temperature; and in response to detecting that a temperature in the chamber is stable at the preset temperature for a preset time, automatically dropping a seed crystal.

In some embodiments, the method may further include: continuously detecting a weight of the seed crystal during a process of automatically dropping the seed crystal; and if the weight of the seed crystal is less than a preset weight threshold, stop dropping the seed crystal and providing a prompt.

In some embodiments, the method may further include: obtaining a real-time image during the process of dropping the seed crystal; comparing the real-time image with a preset reference image; and determining whether to adjust a heating parameter based on a comparison result.

In some embodiments, the method may further include: after the crystal growth is completed, performing an automatic ending operation by controlling the temperature control parameter or the pulling control parameter.

In some embodiments, the method may further include: continuously detecting a crystal weight during the process of automatic ending operation; and if the crystal weight is greater than a preset weight threshold, providing a prompt and controlling a pulling component to move in a reverse direction.

One embodiment of the present disclosure provides a system for controlling crystal growth applied to a crystal preparation process. The system may include at least one storage storing computer instructions; and at least one processor in communication with the at least one storage. When executing the computer instructions, the at least one processor is configured to cause the system to: obtain an actual crystal parameter in a target time slice, wherein the actual crystal parameter may include at least one of an actual crystal mass, an actual crystal diameter, an actual crystal height, or an actual crystal shape; obtain a reference crystal parameter in the target time slice, wherein the reference crystal parameter may include at least one of a reference crystal mass, a reference crystal diameter, a reference crystal height, or a reference crystal shape; determine a temperature control parameter based on the actual crystal parameter and the reference crystal parameter; determine a pulling control parameter based on the actual crystal parameter and the reference crystal parameter; adjust a temperature and a pulling speed in a next time slice after the target time slice respectively based on the temperature control parameter and the pulling control parameter.

In some embodiments, to obtain an actual crystal parameter in a target time slice, the at least one processor may cause the system to: determine a drop height of a liquid level in the target time slice based on the actual crystal mass, a density of a raw material under a molten state, and a size of a chamber; determine the actual crystal height based on a pulling height and the drop height of the liquid level in the target time slice; and determine the actual crystal diameter based on the actual crystal mass and the actual crystal height.

In some embodiments, to obtain a reference crystal parameter in the target time slice, the at least one processor may cause the system to: construct a crystal growth model based on at least one of a preset crystal parameter or a preset crystal growth parameter; and determine, based on the crystal growth model, the reference crystal parameter corresponding to the target time slice.

In some embodiments, the preset crystal parameter may include at least one of a crystal type, a preset crystal density, a preset crystal mass, a preset seed crystal height, a preset seed crystal diameter, a preset shoulder height, a preset height at an equal diameter, a preset diameter at the equal diameter, a preset tail height, a preset crystal tail height, a preset crystal tail diameter, a preset shoulder angle, a preset tail angle, or a ratio of a transition angel between the seed crystal and a shoulder front end to a transition angel between a shoulder end and a front end at the equal diameter.

In some embodiments, the preset crystal growth parameter may include at least one of a preset crystal growth speed or a preset growth coefficient.

In some embodiments, to construct a crystal growth model based on the preset crystal parameter, the at least one processor may cause the system to construct the crystal growth model based on the preset crystal parameter according to a three-dimensional modeling manner.

In some embodiments, to determine a temperature control parameter based on the actual crystal parameter and the reference crystal parameter, the at least one processor may cause the system to: determine a difference between the actual crystal parameter and the reference crystal parameter; and determine the temperature control parameter based on the difference and the reference crystal growth parameter.

In some embodiments, to determine a pulling control parameter based on the actual crystal parameter and the reference crystal parameter, the at least one processor may cause the system to: determine a drop speed of a liquid level in the target time slice based on the actual crystal mass, a melting density of a raw material, and a size of a chamber; and determine the pulling control parameter based on the drop speed of the liquid level and a reference crystal growth parameter.

In some embodiments, before the obtaining an actual crystal parameter in a target time slice, the at least one processor may cause the system to: heat a chamber to a preset temperature; and in response to detecting that a temperature in the chamber is stable at the preset temperature for a preset time, automatically drop the seed crystal.

In some embodiments, the at least one processor may cause the system to: continuously detect a weight of the seed crystal during a process of automatically dropping the seed crystal; and if the weight of the seed crystal is less than a preset weight threshold, stop dropping the seed crystal and provide a prompt.

In some embodiments, the at least one processor may cause the system to: obtain a real-time image during the process of dropping the seed crystal; compare the real-time image with a preset reference image; and determine whether to adjust a heating parameter based on a comparison result.

In some embodiments, the at least one processor may cause the system to: after the crystal growth is completed, perform an automatic ending operation by controlling the temperature control parameter or the pulling control parameter.

In some embodiments, the at least one processor may cause the system to: continuously detect a crystal weight during the process of automatic ending operation; and if the crystal weight is greater than a preset weight threshold, provide a prompt and control a pulling component to move in a reverse direction.

One embodiment of the present disclosure provides a system for controlling crystal growth applied to a crystal preparation process. The system may include an obtaining module, configured to obtain an actual crystal parameter in a target time slice, wherein the actual crystal parameter may include at least one of an actual crystal mass, an actual crystal diameter, an actual crystal height, or an actual crystal shape; and obtain a reference crystal parameter in the target time slice, wherein the reference crystal parameter may include at least one of a reference crystal mass, a reference crystal diameter, a reference crystal height, or a reference crystal shape; a determination module, configured to determine a temperature control parameter based on the actual crystal parameter and the reference crystal parameter; and determine a pulling control parameter based on the actual crystal parameter and the reference crystal parameter; and a control module, configured to adjust a temperature and a pulling speed in a next time slice after the target time slice respectively based on the temperature control parameter and the pulling control parameter.

One embodiment of the present disclosure provides a computer-readable storage medium, the storage medium may store computer instructions. When executed by at least one processor, the instructions may cause the at least one processor to perform following operations: obtaining an actual crystal parameter in a target time slice, wherein the actual crystal parameter may include at least one of an actual crystal mass, an actual crystal diameter, an actual crystal height, or an actual crystal shape; obtaining a reference crystal parameter in the target time slice, wherein the reference crystal parameter may include at least one of a reference crystal mass, a reference crystal diameter, a reference crystal height, or a reference crystal shape; determining a temperature control parameter based on the actual crystal parameter and the reference crystal parameter; determining a pulling control parameter based on the actual crystal parameter and the reference crystal parameter; adjusting a temperature and a pulling speed in a next time slice after the target time slice respectively based on the temperature control parameter and the pulling control parameter.

### BRIEF DESCRIPTION OF THE DRAWINGS

FIG. 1 is a schematic diagram illustrating an exemplary crystal growth control system according to some embodiments of the present disclosure;

FIG. 2 is a schematic diagram illustrating an exemplary computing device according to some embodiments of the present disclosure;

FIG. 3 is a block diagram illustrating an exemplary crystal growth control system according to some embodiments of the present disclosure;

FIG. 4 is a flowchart illustrating an exemplary process for controlling crystal growth according to some embodiments of the present disclosure;

FIG. 5 is a flowchart illustrating an exemplary process for determining a reference crystal parameter according to some embodiments of the present disclosure;

FIG. 6 is an exemplary interface for determining a preset crystal parameter according to some embodiments of the present disclosure;

FIG. 7 is an exemplary interface for determining a preset crystal growth parameter according to some embodiments of the present disclosure;

FIG. 8 is a flowchart illustrating an exemplary process for determining a temperature control parameter according to some embodiments of the present disclosure;

FIG. 9 is a flowchart illustrating an exemplary process for determining a pulling control parameter according to some embodiments of the present disclosure;

FIG. 10 is a diagram illustrating a comparison between an actual crystal diameter and a reference crystal diameter according to some embodiments of the present disclosure;

FIG. 11 is a flowchart illustrating an exemplary process for controlling a drop of a seed crystal according to some embodiments of the present disclosure;

FIG. 12 is a flowchart illustrating an exemplary automatic ending operation according to some embodiments of the present disclosure;

FIG. 13 is a schematic diagram illustrating an exemplary process for controlling crystal growth according to some embodiments of the present disclosure;

FIG. 14 is an exemplary operation interface of an exemplary crystal growth control system according to some embodiments of the present disclosure;

FIG. 15 is an exemplary operation interface for an intermediate frequency power control according to some embodiments of the present disclosure;

FIG. 16 is an exemplary operation interface for a parameter selection according to some embodiments of the present disclosure;

FIG. 17 is an exemplary operation interface for a historical curve query according to some embodiments of the present disclosure;

FIG. 18 is an exemplary operation interface for an operation record query according to some embodiments of the present disclosure;

FIG. 19 is an exemplary operation interface for a weighing calibration according to some embodiments of the present disclosure;

FIG. 20 is a schematic diagram illustrating an application scenario of a crystal growth system according to some embodiments of the present disclosure;

FIG. 21 is a flowchart illustrating an exemplary crystal growth method according to some embodiments of the present disclosure;

FIG. 22 is a flowchart illustrating an exemplary process for determining a first parameter according to some embodiments of the present disclosure;

FIG. 23 is a schematic diagram illustrating a reinforced learning model according to some embodiments of the present disclosure;

FIG. 24 is a flowchart illustrating an exemplary process for determining a target first parameter according to some embodiments of the present disclosure;

FIG. 25 is a flowchart illustrating another exemplary process for determining a target first parameter according to some embodiments of the present disclosure; and

FIG. 26 is a block diagram illustrating an exemplary crystal growth system according to some embodiments of the present disclosure.

### DETAILED DESCRIPTION

In order to illustrate the technical solutions related to the embodiments of the present disclosure, a brief introduction of the drawings referred to the description of the embodiments is provided below. Obviously, drawings described below are only some examples or embodiments of the present disclosure. Those having ordinary skills in the art, without further creative efforts, may apply the present disclosure to other similar scenarios according to these drawings. Unless apparent from the locale or otherwise stated, like reference numerals represent similar structures or operations in the drawings.

It will be understood that the terms “system,” “device,” “unit,” and/or “module” used herein are one method to distinguish different components, elements, parts, sections or assemblies of different levels. However, if other words may achieve the same purpose, the words may be replaced by other expressions.

As used in the disclosure and the appended claims, the singular forms “a,” “an,” and “the” include plural referents unless the content clearly dictates otherwise. In general, the terms “comprise” and “include” merely prompt to include operations and elements that have been clearly identified, and these operations and elements do not constitute an exclusive listing. The methods or devices may also include other operations or elements.

In the present disclosure, a flowchart is used to explain the operations performed by the system according to the embodiment of the present disclosure. It should be understood that the preceding or following operations are not necessarily performed exactly in order. Instead, the operations may be processed in reverse order or simultaneously. At the same time, other operations may be also added to these processes. Alternatively, one operation or several operations may be removed from these processes.

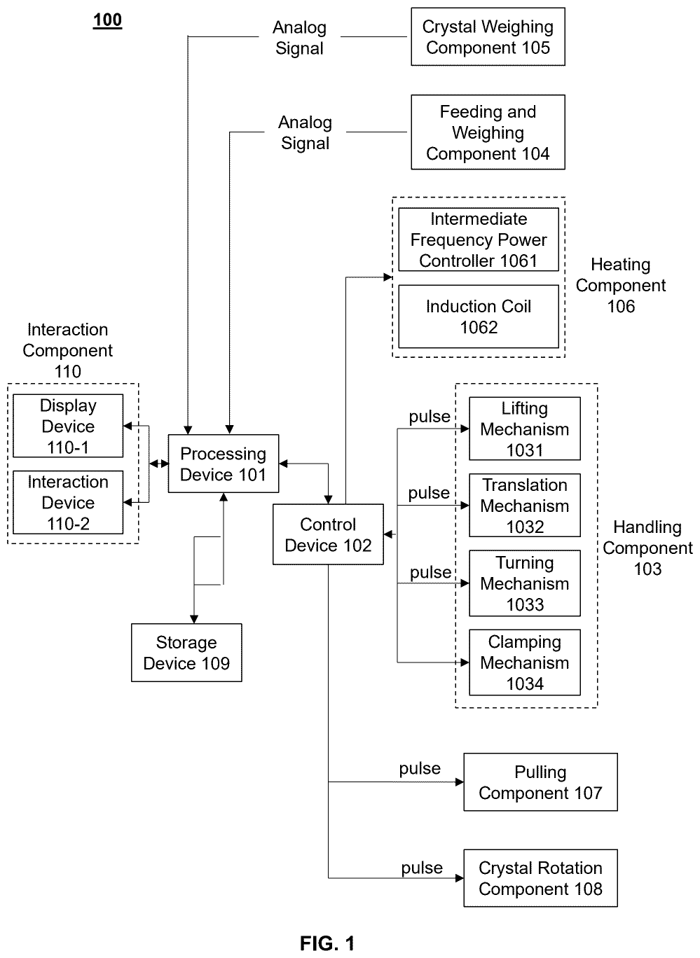

FIG. 1 is a schematic diagram illustrating an exemplary crystal growth control system according to some embodiments of the present disclosure.

In some embodiments, the crystal growth control system 100 may be applied to a growth control of various crystals (e.g., a scintillation crystal (e.g., yttrium lutetium silicate (LYSO), bismuth germanate (BGO)), a spinel crystal) during a growth process. In some embodiments, as shown in FIG. 1, the crystal growth control system 100 may include a processing device 101, a control device 102, a handling component 103, a feeding and weighing component 104, a crystal weighing component 105, a heating component 106, a pulling component 107, a crystal rotation component 108, a storage device 109, and an interaction component 110.

The processing device 101 may be used to process various types of data and/or information involved in the crystal growth process. In some embodiments, the processing device 101 may obtain an actual crystal parameter (e.g., an actual crystal mass, an actual crystal diameter, an actual crystal height, an actual crystal shape) and a reference crystal parameter (e.g., a reference crystal mass, a reference crystal diameter, a reference crystal height, a reference crystal shape), and generate a control instruction (e.g., a control instruction including a temperature control parameter, a pulling control parameter, and/or a crystal rotation control parameter, a feeding control instruction) based on obtained data. The processing device 101 may also transmit the control instruction to the control device 102. The control device 102 may control the pulling component 107, the heating component 106, the crystal rotation component 108, the handling component 103, etc. based on the control instruction. In some embodiments, the processing device 101 may include an industrial control computer. In some embodiments, the processing device 101 may be used as an upper-level control and monitoring device or an upper-level processing device.

The control device 102 may be used to control various operations (e.g., a temperature adjustment, a pulling speed adjustment, a crystal rotation speed adjustment, a feeding operation) involved in the crystal growth process. In some embodiments, the control device 102 may receive the control instruction from the processing device 101 and control the crystal growth process based on the control instruction. In some embodiments, the control device 102 may include a programmable logic controller (PLC). In some embodiments, the control device 102 may be used as a lower-level real-time control device.

In some embodiments, the processing device 101 and/or the control device 102 may include a central processing unit (CPU), an application specific integrated circuit (ASIC), an application specific instruction set processor (ASIP), an image processing unit (GPU), a physical operation processing unit (PPU), a digital signal processor (DSP), a field programmable gate array (FPGA), a programmable logic device (PLD), controller, a microcontroller unit, a reduced instruction set computer (RISC), a microprocessor, or the like, or any combination thereof. In some embodiments, the processing device 101 and the control device 102 may be integrated into a single device. In some embodiments, the control device 102 may be a portion of the processing device 101. In some embodiments, functions of the processing device 101 and functions of the control device 102 may be shared with each other or completed together.

The crystal weighing component 105 may be used to monitor an actual crystal mass (e.g., a seed crystal weight, a crystal weight at any time) at any time and transmit a weighing signal to the processing device 101. The feeding and weighing component 104 may be used to weigh a feeding weight involved in a feeding operation and send a weighing signal to the processing device 101. In some embodiments, the crystal weighing component 105 and the feeding and weighing component 104 may be collectively referred to as a “weighing component.”

The handling component 103 may be used to add a weighed raw material into a growth chamber. In some embodiments, the handling component 103 may include a lifting mechanism 1031, a translation mechanism 1032, a turning mechanism 1033, and a clamping mechanism 1034.

Taking a specific feeding control process as an example, the crystal weighing component 105 may weigh a crystal weight in real time and feedback it to the processing device 101. The processing device 101 may receive the weighing signal to determine whether to perform a feeding operation. If it is determined to perform the feeding operation, the processing device 101 may transmit a control instruction to the control device 102. After receiving the control instruction, the control device 102 may control the feeding and weighing component 104 to weigh a target feeding amount of raw material. After the weighing operation is completed, the control device 102 may control the handling component 103 to add the raw material into the growth chamber. Specifically, the control device 102 may control the clamping mechanism 1034 to clamp a tray containing the raw material, control the lifting mechanism 1031 to move upward to drive the tray upward, control the translation mechanism 1032 to move horizontally to drive the tray to move horizontally to a top of the growth chamber, and control the turning mechanism 1033 to turn over to pour the raw material into the growth chamber, thereby completing the entire feeding process.

The heating component 106 may be used to heat the growth chamber. In some embodiments, the heating component 106 may include an intermediate frequency power controller 1061 and an induction coil 1062. The intermediate frequency power controller 1061 may be used as a closed loop execution unit of temperature control, and used to accurately execute the temperature control instruction of the processing device 101. Specifically, by controlling a current or a voltage of an intermediate frequency power supply, a heating power of the induction coil 1062 may be adjusted. In some embodiments, the intermediate frequency power controller 1061 may perform a signal conversion with the processing device 101 and/or the control device 102 via an RS232-485 converter to transmit temperature data of the induction coil 1062. It should be noted that the heating component 106 may also be directly controlled by the processing device 101, or the control device 102 may be integrated into the processing device 101, and the heating component 106 may be controlled by the control device 102.

The pulling component 107 may be used to drive a seed crystal or a crystal to move upward and downward. For example, before the crystal growth is started, the pulling component 107 may control a pulling rod carrying the seed crystal to move downward. As another example, when the crystal growth is completed, the pulling component 107 may perform an ending operation to pull the crystal upward and away from a liquid surface of the raw material. In some embodiments, the pulling component 107 may include a pulling motor.

The crystal rotation component 108 may be used to drive a seed crystal or a crystal to rotate. For example, during the crystal growth process, the crystal rotation component 108 may control the rotation of the crystal. In some embodiments, the crystal rotation component 108 may include a rotating motor.

The storage device 109 may store various types of data and/or information involved in the crystal growth process. In some embodiments, the storage device 109 may store a parameter (e.g., a temperature, a pulling speed, a crystal rotation speed, a crystal weight), a control instruction, etc., during the crystal growth process. In some embodiments, the storage device 109 may be directly connected to or in communication with one or more components (e.g., the processing device 101, the control device 102, the handling component 103, the feeding and weighing component 104, the crystal weighing component 105, the heating components 106) of the crystal growth control system 100. The one or more components of the crystal growth control system 100 may access the data and/or instructions stored in the storage device 109 via a network or directly. In some embodiments, the storage device 109 may be a portion of the processing device 101 and/or the control device 102. Relevant data (e.g., a temperature control parameter, a pulling control parameter, a reference crystal parameter) during the crystal growth control process may be recorded in the storage device 109 in real time.

In some embodiments, the storage device 109 may store data and/or instructions that the processing device 101 may execute or use to perform exemplary methods described in the present disclosure. In some embodiments, the storage device 109 may include a mass storage, a removable storage, a volatile read-write storage, a read-only storage (ROM), or the like, or any combination thereof. Exemplary mass storages may include a magnetic disk, an optical disk, a solid-state disk, or the like. Exemplary removable storages may include a flash drive, a floppy disk, an optical disk, a memory card, a compact disk, a magnetic tape, or the like. Exemplary volatile read-only memories may include a random-access memory (RAM). Exemplary RAMs may include a dynamic RAM (DRAM), a double rate synchronous dynamic RAM (DDR SDRAM), a static RAM (SRAM), a thyristor RAM (T-RAM), a zero capacitance RAM (Z-RAM), or the like. Exemplary ROMs may include a mask ROM (MROM), a programmable ROM (PROM), an erasable programmable ROM (EPROM), an electronically erasable programmable ROM (EEPROM), a compact disk ROM (CD-ROM), a digital General disk ROM, etc. In some embodiments, the storage device 109 may be implemented on a cloud platform. Merely by way of example, the cloud platform may include a private cloud, a public cloud, a hybrid cloud, a community cloud, a distributed cloud, an inter-cloud, a multi-cloud, or the like, or any combination thereof.

The interaction component 110 may be used to interact with a user or other components of the crystal growth control system 100. In some embodiments, the interaction component 110 may include a display device 110-1 and an interaction device 110-2. The display device 110-1 may include a nixie tube display, a two-dimensional display, a three-dimensional display, etc. The interaction device 110-2 may include an input device. The input device may include a mouse, a keyboard, a voice input device, etc.

In some embodiments, the processing device 101 may perform a human-computer interaction with an operator (e.g., a crystal preparation engineer) through the display device 110-1 and the interaction device 110-2. The operator may query an actual crystal parameter, a temperature control parameter, a pulling control parameter, etc. via the display device 110-1.

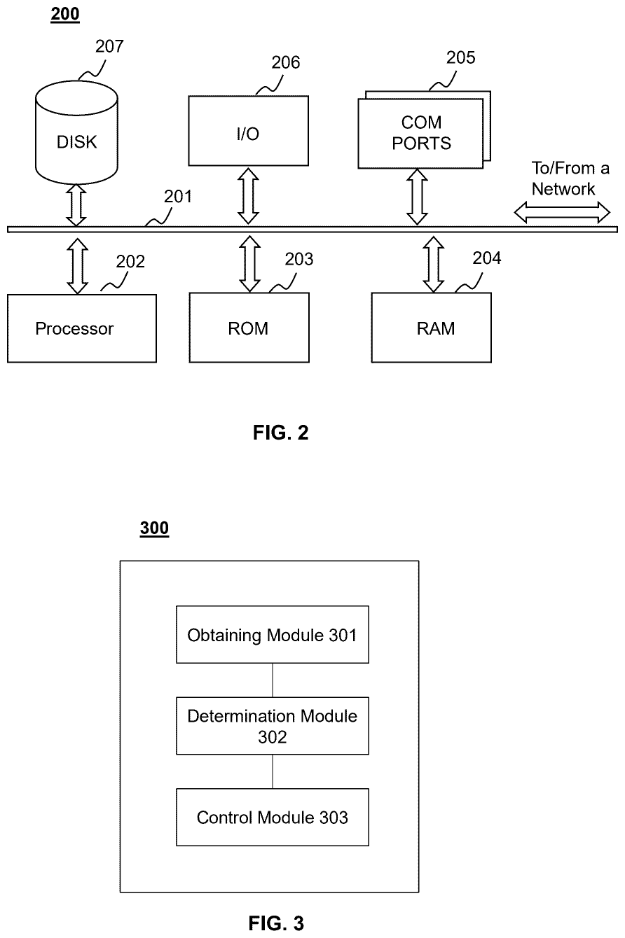

FIG. 2 is a schematic diagram illustrating an exemplary computing device 200 according to some embodiments of the present disclosure.

In some embodiments, the processing device 101, the control device 102, and/or the storage device 109 may be implemented on the computing device 200, and configured to implement functions disclosed in the present disclosure.

The computing device 200 may include any component that can be used to implement the system described in the present disclosure. For example, a PLC may be implemented on the computing device 200 through hardware, software programs, firmware, or any combination thereof. For convenience, only one computer is shown in the figure, but computation functions related to the feeding control described in the present disclosure may be implemented by a group of similar platforms in a distributed manner to distribute a processing load of the system.

The computing device 200 may include a communication port 205 connected to a network for data communication. The computing device 200 may include a processor 202 (e.g., a CPU) that may execute program instructions in the form of one or more processors. An exemplary computer platform may include an internal bus 201 and various forms of program storages and data storages, for example, a hard disk 207, a read-only memory (ROM) 203, or a random-access memory (RAM) 204, for storing various data files processed and/or transferred by the computer. The computing device may also include program instructions executed by the processor 202 and stored in the ROM 203, the RAM 204, and/or other types of non-transitory storage media. The methods and/or processes described in the present disclosure may be implemented in a form of program instructions. The computing device 200 may also include an input/output component 206 for supporting input/output between the computer and other components. The computing device 200 may also receive programs and data described in the present disclosure through a network communication.

Merely for illustration, only one processor is described in the computing device 200. However, it should be noted that the computing device 200 in the present disclosure may also include multiple processors, thus operations and/or method steps that are performed by one processor as described in the present disclosure may also be jointly or separately performed by the multiple processors. For example, if in the present disclosure the processor of the computing device 200 executes both operation A and operation B, it should be understood that operation A and operation B may also be performed by two or more different processors jointly or separately in the computing device 200 (e.g., a first processor executes operation A and a second processor executes operation B, or the first and second processors jointly execute operations A and B).

FIG. 3 is a block diagram illustrating an exemplary crystal growth control system according to some embodiments of the present disclosure.

As shown in FIG. 3, a crystal growth control system 300 may include an obtaining module 301, a determination module 302, and a control module 303. In some embodiments, the crystal growth control system 300 may be implemented by the processing device 101 and/or the control device 102, or integrated into the processing device 101 and/or the control device 102.

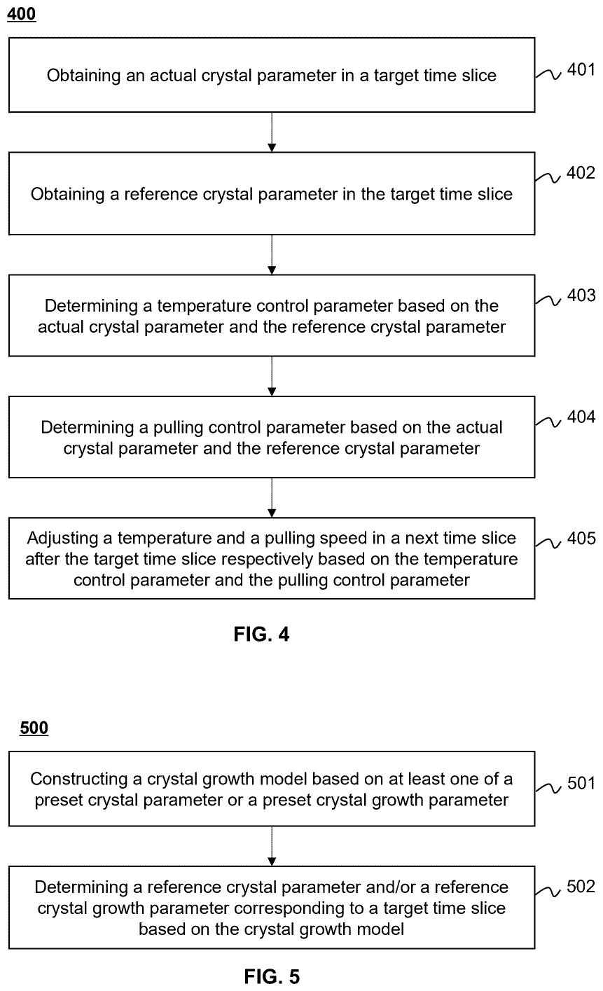

The obtaining module 301 may be used to obtain an actual crystal parameter in a target time slice. In some embodiments, the obtaining module 301 may be used to obtain a reference crystal parameter in the target time slice. More descriptions regarding obtaining the actual crystal parameter and the reference crystal parameter in the target time slice may be found in FIG. 4 and the descriptions thereof, which are not repeated here.

The determination module 302 may be used to determine a temperature control parameter based on the actual crystal parameter and the reference crystal parameter. In some embodiments, the determination module 302 may be used to determine a pulling control parameter based on the actual crystal parameter and the reference crystal parameter. More descriptions regarding determining the temperature control parameter and the pulling control parameter may be found in FIG. 4 and the descriptions thereof, which are not repeated here.

The control module 303 may be configured to adjust a temperature and a pulling speed in a next time slice after the target time slice, respectively, based on the temperature control parameter and the pulling control parameter. More descriptions regarding adjusting the temperature and the pulling speed in the next time slice after the target time slice may be found in FIG. 4 and the descriptions thereof, which are not repeated here.

It should be understood that the system and the modules thereof shown in FIG. 3 may be implemented in various ways. For example, in some embodiments, the system and the modules thereof may be implemented by hardware, software, or a combination of software and hardware. The hardware portion may be realized by dedicated logic. The software portion may be stored in the memory and executed by an appropriate instruction execution system, such as a microprocessor or a dedicated design hardware. Those skilled in the art may understand that the above methods and systems may be implemented using computer-executable instructions and/or included in processor control codes. For example, such codes may be provided on a carrier medium such as a disk, CD, or DVD-ROM, a programmable memory such as a read-only memory (firmware), or a data carrier such as an optical or an electronic signal carrier. The system and the modules thereof described in the present disclosure may not only be implemented by a hardware circuit such as a very large-scale integrated circuit or a gate array, a semiconductor such as a logic chip, a transistor, etc., or a programmable hardware device such as a field programmable gate array, a programmable logic device, etc. The system and the modules thereof also may be implemented by software executed by various types of processors. The system and the modules thereof also may be implemented by a combination of the above hardware circuit and software (e.g., firmware).

It should be noted that the above description of the crystal growth control system 300 and the modules thereof are merely provided for the purposes of illustration, and not intended to limit the scope of the present disclosure. It should be understood that for those skilled in the art, after understanding the principle of the system, it may be possible to arbitrarily combine various modules, or form a subsystem to connect with other modules without departing from the principle. For example, the obtaining module 301, the determination module 302, and the control module 303 disclosed in FIG. 3 may be different modules in the system, or a single module which can implement the functions of more than two modules. As another example, modules in the crystal growth control system 300 may share a storage module, or each module may have its own storage module. Such variations do not depart from the scope of the present disclosure.

FIG. 4 is a flowchart illustrating an exemplary process for controlling crystal growth according to some embodiments of the present disclosure. In some embodiments, process 400 may be performed by a processing device (e.g., the processing device 101) and/or a control device (e.g., the control device 102). For example, process 400 may be stored in a storage device (e.g., a storage device, a storage unit of the processing device and/or the control device) as a form of programs or instructions. When the processor 202 or the modules shown in FIG. 3 execute the programs or the instructions, process 400 may be implemented. In some embodiments, process 400 may be accomplished with one or more additional operations not described, and/or without one or more of the operations discussed. Additionally, the order of operations as illustrated in FIG. 4 is not intended to be limiting.

In 401, an actual crystal parameter in a target time slice may be obtained. In some embodiments, operation 401 may be executed by the obtaining module 301.

Generally, a crystal growth process starts from preparing for seeding (or after the seeding is completed, that is, from when the crystal starts to grow) to growing to a crystal with a target shape. The crystal growth process may include a plurality of stages (e.g., a seeding stage, a shouldering stage, an equal diameter stage, an ending stage) and may take a relatively long time (e.g., 10 hours, 30 hours, 50 hours, 60 hours, 100 hours). Accordingly, the processing device and/or the control device may divide the crystal growth process into a plurality of moments or a plurality of time slices. In some embodiments, time intervals among the plurality of moments may be the same or different. In some embodiments, time lengths (also referred to simply as “duration”) of the plurality of time slices may be the same or different. For instance, the time length of the time slice may be 10 seconds, 15 seconds, 30 seconds, 1 minute, 10 minutes, etc.

In some embodiments, the processing device and/or the control device may determine the time lengths and/or a count of the plurality of time slices according to a related parameter (e.g., a crystal type, a crystal size, a growth stage) of a crystal to be grown. For example, a time length (e.g., 5 seconds, 10 seconds) of a time slice corresponding to the seeding stage or the shouldering stage may be different from a time length (e.g., 30 seconds, 1 minute) of a time slice corresponding to the equal diameter stage.

In some embodiments, the processing device and/or the control device may determine the time lengths and/or the count of the plurality of time slices according to a control accuracy. For example, for a crystal growth process for which a total growth time has been determined, the greater the count of time slices (or the shorter the time length of a single time slice is) is, the higher the control accuracy may be. Conversely, the lower the control accuracy may be. For example, it is assumed that the total growth time is 20 hours, the processing device and/or the control device may divide the total growth time into 1200 time slices according to the control accuracy. The time length of a single time slice may be 1 minute. As another example, the processing device and/or the control device may also divide the total growth time into 400 time slices. The time length of a single time slice may be 3 minutes.

In some embodiments, the processing device and/or the control device may comprehensively consider the control accuracy and a data processing capability of the system to determine the time lengths and/or the count of the plurality of time slices. For example, in combination with the foregoing, the greater the count of time slices is (or the shorter the time length of a single time slice is), the higher the control accuracy may be, but the higher the data processing capability required may be. The processing device and/or the control device may comprehensively determine the time lengths and/or the count of the plurality of time slices under a premise that the required data processing capacity does not exceed a normal data processing capacity.

In some embodiments, the processing device and/or the control device may select any one of the plurality of time slices as the target time slice. In some embodiments, the processing device and/or the control device may select a time slice corresponding to a specific stage (e.g., the equal diameter stage, the ending stage) as the target time slice. In some embodiments, the processing device and/or the control device may select a corresponding time slice as the target time slice according to actual requirements.

In some embodiments, the actual crystal parameter may include an actual crystal mass, an actual crystal diameter, an actual crystal height, an actual crystal shape, or the like, or any combination thereof.

In some embodiments, the actual crystal parameter in the target time slice may characterize an actual growth condition of the crystal in the target time slice. For example, if the target time slice is 10:00:00-10:01:00, the actual crystal mass in the target time slice may be a weight of the crystal increased in the time period of 10:00:00-10:01:00; the actual crystal diameter in the target time slice may be an average value of crystal diameters in the time period of 10:00:00-10:01:00; the actual crystal height in the target time slice may be a height of the crystal increased in the time period of 10:00:00-10:01:00; the actual crystal shape in the target time slice may be a shape of the crystal in the time period of 10:00:00-10:01:00.

In some embodiments, the processing device and/or the control device may obtain an actual crystal mass at an end time and an actual crystal mass at a start time of the target time slice, and determine the actual crystal mass in the target time slice based on a difference between the two masses.

In some embodiments, the processing device and/or the control device may determine the actual crystal height in the target time slice based on a pulling height and a drop height of a liquid level in the target time slice. Specifically, the processing device and/or the control device may determine a sum of the pulling height (which may be expressed as h₁) and the drop height of the liquid level (which may be expressed as h₂) in the target time slice as the actual crystal height (which may be expressed as h) in the target time slice. That is, h=h₁+h₂.

In some embodiments, the processing device and/or the control device may determine the drop height of the liquid level according to a reading of a grating ruler in a crystal growth device. Specifically, the processing device and/or the control device may determine a difference between a reading (which may be expressed as hₜ₂) of the grating ruler at the end time and a reading (which may be expressed as hₜ₁) of the grating ruler at the starting time of the target time slice as the pulling height. That is, h₁=hₜ₂−hₜ₁. In some embodiments, the processing device and/or the control device may determine the pulling height according to an operating parameter of the pulling component. Specifically, the processing device and/or control device may determine the corresponding pulling height (e.g., h₁=n×Δh₁) according to a count of operations of a pulling motor (which may be expressed as n) and a pulling height corresponding to one operation (which may be expressed as Δh₁).

In some embodiments, the processing device and/or the control device may determine the drop height of the liquid level based on the actual crystal mass, a density of a raw material under a molten state, and a size of a chamber. Specifically, for example, if no additional raw material for crystal growth is added into the chamber within the target time slice, the processing device and/or the control device may determine the drop height of the liquid level based on formula (1):

$${h}_{2} = \frac{m / {ρ}_{1}}{{S}_{1}} , \qquad ( 1 )$$

wherein h₂ represents the drop height of the liquid level; m represents the actual crystal mass; ρ₁ represents the density of the raw material under the molten state; S₁ represents a cross-sectional area of the chamber. In some embodiments, if the cross section of the chamber is circular, the cross-sectional area of the chamber may be determined based on a diameter of the circle. If the cross section of the chamber is rectangular, the cross-sectional area of the chamber may be determined based on side lengths of the rectangle.

As another example, if additional raw material for crystal growth is added into the chamber within the target time slice, the processing device and/or the control device may determine the drop height of the liquid level based on formula (2):

$${h}_{3} = \frac{( m - Δ m ) / {ρ}_{1}}{{S}_{1}} , \qquad ( 2 )$$

wherein h₃ represents a drop height of a liquid level; m represents an actual crystal mass; Δm represents a feeding mass of raw material; ρ₁ represents a density of the raw material under a molten state; S₁ represents a cross-sectional area of a chamber. In some embodiments, if the feeding mass of the raw material is equal to the actual crystal mass, the drop height of the liquid level may be zero. Accordingly, the actual crystal height in the target time slice may be equal to the pulling height. That is, h=h₁.

In some embodiments, the processing device and/or the control device may determine the actual crystal diameter based on the actual crystal mass and the actual crystal height. Specifically, the processing device and/or the control device may determine the actual crystal diameter based on formula (3):

$$d = 2 \sqrt{\frac{m}{{ρ}_{s} \times h \times π}} , \qquad ( 3 )$$

wherein d represents an actual crystal diameter; m represents an actual crystal mass; ρₛ represents a crystal density; h represents an actual crystal height.

In some embodiments, the processing device and/or the control device may obtain the actual crystal shape in the target time slice from an image acquisition device (e.g., a 3D camera). In some embodiments, the processing device and/or the control device may construct a crystal growth model based on the actual crystal mass, the actual crystal diameter, the actual crystal height, the crystal density, etc., and determine the actual crystal shape based on the crystal growth model. More descriptions regarding constructing the crystal growth model may be found in FIG. 5 and the description thereof, which are not repeated here.

In 402, a reference crystal parameter in the target time slice may be obtained. In some embodiments, operation 402 may be executed by the obtaining module 301.

In some embodiments, the reference crystal parameter may include a reference crystal mass, a reference crystal diameter, a reference crystal height, a reference crystal shape, or the like, or any combination thereof.

In some embodiments, the reference crystal parameter in the target time slice may characterize a theoretical growth condition of the crystal in the target time slice during the crystal growth process. For example, if the target time slice is 10:00:00-10:01:00, the reference crystal mass in the target time slice may be a weight of the crystal theoretically increased in the time period of 10:00:00-10:01:00; the reference crystal diameter in the target time slice may be an average value of theoretical crystal diameters in the time period of 10:00:00-10:01:00; the reference crystal height in the target time slice may be a height of the crystal theoretically increased in the time period of 10:00:00-10:01:00; the reference crystal shape in the target time slice may be a theoretical shape of the crystal in the time period of 10:00:00-10:01:00.

In some embodiments, the processing device and/or the control device may construct (e.g., according to a three-dimensional modeling method) a crystal growth model based on a preset crystal parameter and/or a preset crystal growth parameter, and determine the reference crystal parameter in the target time slice based on the crystal growth model. In some embodiments, the processing device and/or the control device may also determine a reference crystal growth parameter (e.g., a reference crystal growth speed, a reference growth coefficient) corresponding to the target time slice based on the crystal growth model. In the present disclosure, “reference crystal parameter” and “reference crystal growth parameter” may also be collectively referred to as “reference crystal parameter.” That is, the reference crystal parameter may include the reference crystal mass, the reference crystal diameter, the reference crystal height, the reference crystal shape, the reference crystal growth speed, the reference growth coefficient, or the like, or any combination thereof.

In some embodiments, the crystal growth model may characterize a theoretical growth of the crystal throughout the growth process. In some embodiments, the preset crystal parameter may include a crystal type, a preset crystal density, a preset crystal mass, a preset seed crystal height, a preset seed crystal diameter, a preset shoulder height, a preset height at an equal diameter, a preset diameter at the equal diameter, a preset tail height, a preset crystal tail height, a preset crystal tail diameter, a preset shoulder angle, a preset tail angle, a ratio of a transition angel between the seed crystal and a shoulder front end to a transition angel between a shoulder end and a front end at the equal diameter, or the like, or any combination thereof. In some embodiments, the preset crystal growth parameter may include a preset crystal growth speed (e.g., preset crystal growth speeds corresponding to different crystal growth stages), a preset growth coefficient (e.g., preset growth coefficients corresponding to different crystal growth stages), or the like, or any combination thereof. More descriptions of the crystal growth model may be found in FIGS. 5-7 and the descriptions thereof, which are not repeated here.

In 403, a temperature control parameter may be determined based on the actual crystal parameter and the reference crystal parameter. In some embodiments, operation 403 may be executed by the determination module 302.

In some embodiments, the temperature control parameter may be used to control a temperature of a furnace in the crystal growth device. Specifically, the temperature control parameter may include a change of a heating parameter (e.g., a power change of an intermediate frequency power supply, a current change of the intermediate frequency power supply, a power change of an induction coil, a current change of the induction coil) used to control a heating component (e.g., the intermediate frequency power supply, the induction coil). In some embodiments, the temperature control parameter may also include a change of a heating exchange parameter (e.g., a flow change of a circulating water, a flow speed change of the circulating water) used to control a heating exchange component (e.g., a heating exchange component of circulating water on a furnace body of the crystal growth device) in the crystal growth device.

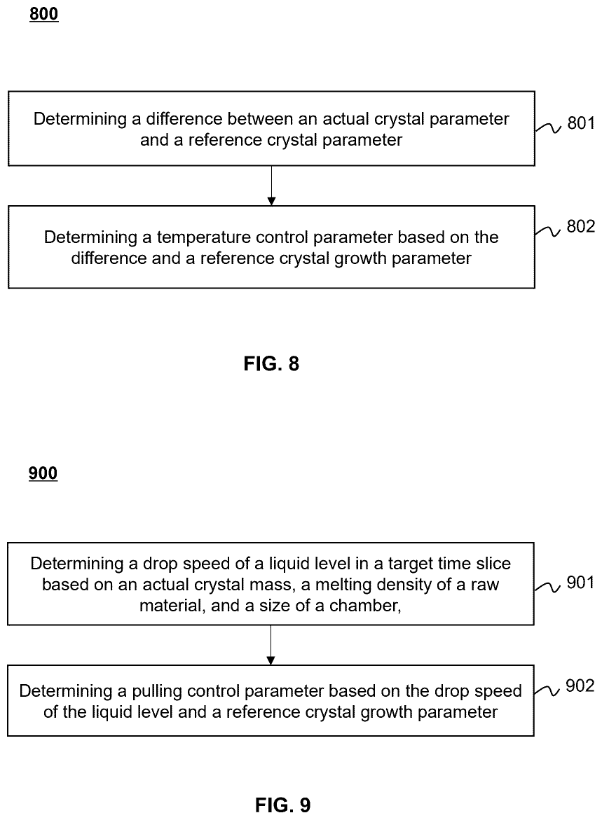

In some embodiments, the processing device and/or the control device may determine the temperature control parameter based on a difference between the actual crystal parameter and the reference crystal parameter and the reference crystal growth parameter (e.g., the reference growth coefficient). More descriptions regarding determining the temperature control parameter may be found in FIG. 8 and the description descriptions, which are not repeated here.

In 404, a pulling control parameter may be determined based on the actual crystal parameter and the reference crystal parameter. In some embodiments, operation 404 may be executed by the determination module 302.

In some embodiments, the pulling control parameter may be used to control a pulling process of a pulling component (e.g., a pulling motor) in the crystal growth device. Specifically, the pulling control parameter may include a parameter for controlling a change of a pulling parameter (e.g., a change of a rotation speed of the pulling motor, a change of a power of the pulling motor) of the pulling component.

In some embodiments, the processing device and/or the control device may determine or adjust the pulling control parameter based on the actual crystal parameter and the reference crystal parameter (e.g., a difference between the actual crystal mass and the reference crystal mass, a difference between the actual crystal diameter and the reference crystal diameter). For example, if the difference between the actual crystal mass and the reference crystal mass is greater than a preset threshold, the processing device and/or the control device may increase the pulling control parameter.

In some embodiments, the processing device and/or the control device may determine the pulling control parameter based on a drop speed of the liquid level and the reference crystal growth parameter (e.g., the reference crystal growth speed). Specifically, in combination with formula (1) and formula (2) described above, the processing device and/or the control device may obtain the actual crystal mass, the melting density of the raw material, the size of the chamber, and a feeding mass of raw material in the target time slice (if any), determine the drop height of the liquid level in the target time slice, and then determine the drop speed of the liquid level in the target time slice. Further, the pulling control parameter may be determined based on the drop speed of the liquid level and the reference crystal growth parameter. More descriptions regarding determining the pulling control parameter may be found in FIG. 9 and the descriptions thereof, which are not repeated here.

In 405, a temperature and a pulling speed in a next time slice after the target time slice may be adjusted respectively based on the temperature control parameter and the pulling control parameter. In some embodiments, operation 405 may be executed by the control module 303.

In some embodiments, the processing device and/or the control device may adjust the crystal growth in the next target time slice by adjusting the temperature (e.g., the temperature of the furnace in the crystal growth device) and the pulling speed (e.g., the pulling speed of the pulling motor) in the next target time slice based on a difference between an actual situation of the crystal and a theoretical situation of the crystal in the target time slice.

In some embodiments, the processing device and/or the control device may adjust the temperature in the next time slice after the target time slice based on a heating parameter and a temperature control parameter of the heating component in the target time slice. In some embodiments, the heating parameter of the heating component in the target time slice may be an average heating parameter of the heating component in the target time slice (e.g., an average power of the induction coil, an average current of the induction coil) or a value of the heating parameter (e.g., a power value of the induction coil, a current value of the induction coil) at the end time of the target time slice.

In some embodiments, similarly, the processing device and/or the control device may adjust the pulling speed in the next time slice after the target time slice based on the pulling speed and the pulling control parameter of the pulling component in the target time slice. In some embodiments, the pulling speed in the target time slice may be an average pulling speed in the target time slice or a pulling speed at the end time of the target time slice.

Merely by way of example, if the target time slice is 10:00:00-10:01:00, the temperature of the furnace in the crystal growth device in the target time slice is 2000° C., the pulling speed is 10 centimeters/hour, the power of the induction coil is 2200 KW (or the current is 10 A), the rotation speed of the pulling motor is 1000 revolutions/minute (or the power is 3 KW), the temperature control parameter determined according to operation 403 is that the power change of the induction coil is +1 KW (or a current change is +0.1 A), and the pulling control parameter determined according to operation 404 is that the rotation speed change of the pulling motor is-3 revolutions/minute (or the power is −0.1 KW). Accordingly, in the next time slice 10:01:00˜10:02:00, the control module 303 may adjust the power of the induction coil in the crystal growth device to 2201 kW (or adjust the current of the induction coil to 10.1 A), and adjust the rotation speed of the pulling motor to 997 revolutions/minute (or adjust the power of the pulling motor to 2.9 KW).

In some embodiments, the processing device and/or the control device may execute operations 401 to 405 in sequence in multiple cycles to control the entire crystal growth process to achieve an automatic crystal growth control.

In some embodiments, the processing device and/or the control device may also determine or adjust a crystal rotation control parameter based on the actual crystal parameter and the reference crystal parameter (e.g., the difference between the actual crystal mass and the reference crystal mass, the difference between the actual crystal diameter and the reference crystal diameter). The crystal rotation control parameter may include a parameter for controlling a crystal rotation parameter change (e.g., a rotation speed change of a crystal rotation motor, a power change of a crystal rotation motor) of a crystal rotation component. For example, if the difference between the actual crystal mass and the reference crystal mass is greater than a preset threshold, the processing device and/or the control device may increase the crystal rotation control parameter.

According to some embodiments of the present disclosure, during the crystal growth control process, the temperature control parameter and the pulling control parameter in the next time slice may be determined based on the actual crystal parameter and the reference crystal parameter in a previous time slice. The temperature and the pulling speed in the next time slice may be adjusted based on the temperature control parameter and the pulling control parameter, respectively. Since the division of time slices can be determined according to a parameter related to the crystal to be grown and/or a control accuracy requirement, the entire crystal growth process can be controlled according to operations 401-405 efficiently and accurately. In addition, since the reference crystal parameter is determined based on the theoretical crystal growth model, the actual crystal parameter of the crystal finally grown would be close to the theoretical crystal parameter.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, process 400 may include a storing operation. In the storing operation, the processing device and/or the control device may store information and/or data (e.g., the temperature control parameter, the pulling control parameter) involved in process 400 in a storage device (e.g., the storage device 109). As another example, the reference crystal parameter and/or the reference crystal growth parameter may be a system default value, a user-defined value, etc., instead of determined based on the crystal growth model.

FIG. 5 is a flowchart illustrating an exemplary process for determining a reference crystal parameter according to some embodiments of the present disclosure. In some embodiments, process 500 may be performed by a processing device (e.g., the processing device 101) and/or a control device (e.g., the control device 102). For example, process 500 may be stored in a storage device (e.g., a storage device, a storage unit of the processing device and/or the control device) in a form of programs or instructions. When the processor 202 or the modules shown in FIG. 3 execute the programs or instructions, process 500 may be implemented. In some embodiments, process 500 may be accomplished with one or more additional operations not described, and/or without one or more of the operations discussed. Additionally, the order of the operations as illustrated in FIG. 5 is not intended to be limiting.

In 501, a crystal growth model may be constructed based on at least one of a preset crystal parameter or a preset crystal growth parameter. In some embodiments, operation 501 may be executed by the determination module 302.

In some embodiments, the crystal growth model may characterize a theoretical growth condition of the crystal in an entire growth process. In some embodiments, the crystal growth model may be used to determine the reference crystal parameter that changes over time.

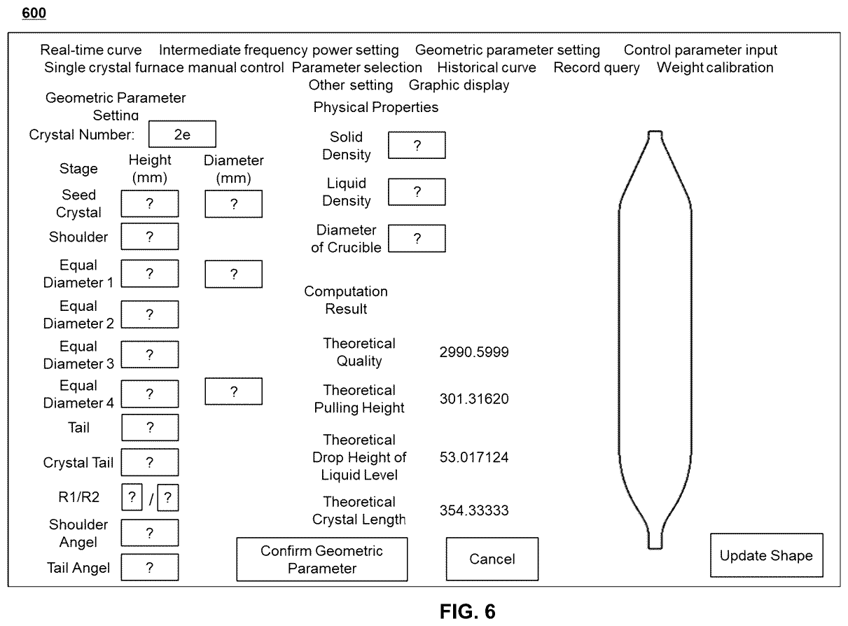

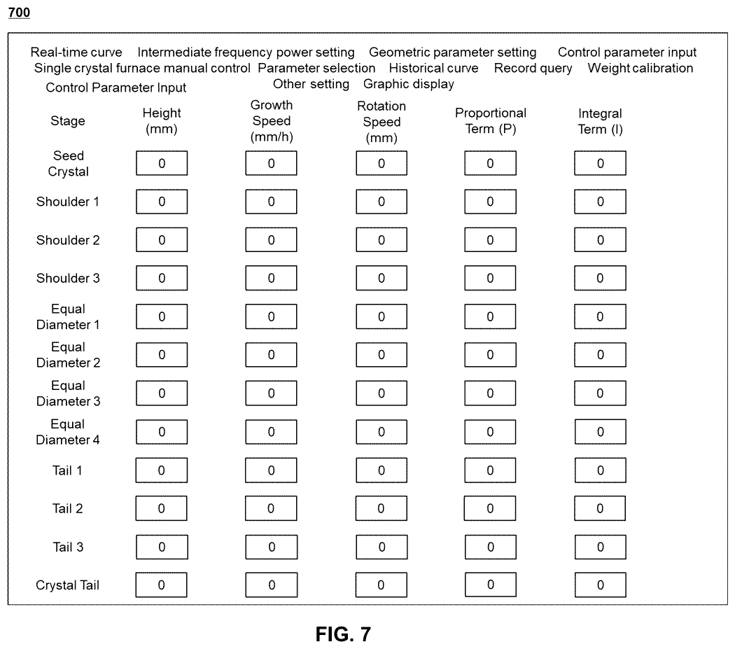

In some embodiments, the preset crystal parameter may include a crystal type, a preset crystal density, a preset crystal mass, a preset seed crystal height, a preset seed crystal diameter, a preset shoulder height, a preset height at an equal diameter, a preset diameter at the equal diameter, a preset tail height, a preset crystal tail height, a preset crystal tail diameter, a preset shoulder angle, a preset tail angle, a ratio of a transition angel between the seed crystal and a shoulder front end to a transition angel between a shoulder end and a front end at the equal diameter, or the like, or any combination thereof. In some embodiments, the preset crystal growth parameter may include a preset crystal growth speed (e.g., preset crystal growth speeds corresponding to different crystal growth stages), a preset growth coefficient (e.g., preset growth coefficients corresponding to different crystal growth stages), or the like, or any combination thereof. More descriptions of the preset crystal parameter and/or the preset crystal growth parameter may be found in FIGS. 6-7 and the descriptions thereof, which are not repeated here.

In some embodiments, the preset crystal parameter and/or the preset crystal growth parameter may be automatically set by the system (e.g., determined based on an empirical value, big data statistics, machine learning), manually set by a user, or semi-automatically set (i.e., a combination of automatic setting and manual setting). For example, according to a crystal type, the processing device and/or the control device may automatically determine various other preset crystal parameters and/or preset crystal growth parameters corresponding to the crystal type. As another example, according to a crystal type and a crystal size, the processing device and/or the control device may automatically determine various other preset crystal parameters and/or preset crystal growth parameters corresponding to the crystal type.

In some embodiments, the processing device and/or the control device may construct a crystal growth model based on the preset crystal parameter and/or the preset crystal growth parameter according to a three-dimensional modeling method. Exemplary three-dimensional modeling algorithms may be constructing a geometric model according to the preset crystal parameter and/or the preset crystal growth parameter.

In some embodiments, when constructing the crystal growth model, the processing device and/or the control device may also consider a parameter that may be involved in the crystal growth process, such as an internal stress, an internal defect, an internal component distribution, a continuity of different crystal growth stages (to avoid parameter mutations), etc., so that the constructed crystal growth model may accurately reflect the entire crystal growth process.

In some embodiments of the present disclosure, by constructing the crystal growth model based on the preset crystal parameter and/or the preset crystal growth parameter, the crystal growth model may not only reflect shape data of the crystal, but also reflect control data of each growth stage. Accordingly, the crystal growth process can be controlled accurately and effectively based on the crystal growth model.

In 502, a reference crystal parameter and/or a reference crystal growth parameter corresponding to a target time slice may be determined based on the crystal growth model. In some embodiments, operation 502 may be executed by the determination module 302.

As described above, the crystal growth model may characterize the theoretical growth condition of the crystal in the entire growth process. Accordingly, the processing device and/or the control device may determine the reference crystal parameter (which may reflect a theoretical growth condition of the crystal in the target time slice) corresponding to the target time slice based on the crystal growth model. For example, the processing device and/or the control device may input the target time slice into the crystal growth model and determine the reference crystal parameter and/or the reference crystal growth parameter corresponding to the target time slice based on an output of the crystal growth model.

According to some embodiments of the present disclosure, the crystal growth model may be constructed based on the preset crystal parameter and/or the preset crystal growth parameter, which may characterize the theoretical growth of the crystal in the entire growth process. Accordingly, the reference crystal parameter and/or the reference crystal growth parameter corresponding to any time or any time slice in the growth process can be determined based on the crystal growth model. Furthermore, a subsequent growth process can be controlled accurately and effectively based on the determined reference crystal parameter and/or the reference crystal growth parameter.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, after the crystal growth model is constructed, the processing device and/or the control device may store the crystal growth model in a storage device (e.g., the storage device 109).

FIG. 6 is an exemplary interface for determining a preset crystal parameter according to some embodiments of the present disclosure. FIG. 7 is an exemplary interface for determining a preset crystal growth parameter according to some embodiments of the present disclosure.

As shown in FIG. 6, a user may manually input a preset crystal parameter (e.g., “geometric parameter” shown in the figure) via an interface 600. Referring to FIG. 5, the preset crystal parameter may include a crystal type (e.g., a crystal number), a preset crystal density (e.g., a solid density, a liquid density), a preset crystal mass, a preset seed crystal height, a preset seed crystal diameter, a preset shoulder height, a preset height at an equal diameter (e.g., a height at equal diameter 1, a height at equal diameter 2, a height at equal diameter 3, a height at equal diameter 4), a preset diameter at the equal diameter, a preset tail height, a preset crystal tail height, a preset crystal tail diameter, a preset shoulder angle, a preset tail angle, R1/R2 (i.e., a ratio of a transition angel between the seed crystal and a shoulder front end (e.g., shoulder 1 in FIG. 7) to a transition angel between a shoulder end (e.g., shoulder 3 in FIG. 7) and a front end at the equal diameter (e.g., equal diameter 1 in FIG. 6 or FIG. 7), or the like, or any combination thereof.

In some embodiments, after the user inputs the preset crystal parameter, the interface 600 may also display a computation result determined based on the preset crystal parameter, for example, a theoretical mass, a theoretical pulling height, a theoretical drop height of a liquid level, a theoretical crystal length, etc.

In some embodiments, the interface 600 may also display a diameter of a crucible. The user may also manually input the diameter of the crucible.

In some embodiments, after the user inputs the preset crystal parameter, the processing device and/or the control device may construct a preliminary crystal growth model based on the preset crystal parameter. The processing device and/or the control device may display a preview of an outline drawing corresponding to the preliminary crystal growth model via the interface 600. Through the outline drawing preview, the user may intuitively change a corresponding parameter. In addition, through the computation result (e.g., the theoretical mass, the theoretical pulling height, the theoretical drop height of the liquid level, the theoretical crystal length) displayed on the interface 600, the user may check whether a current crystal growth model satisfies a target design requirement.

Further, as shown in FIG. 7, the user may input a preset crystal growth parameter (e.g., “control parameter” shown in the figure) via an interface 700. As shown in FIG. 7, a column of “height” on the left side of the figure is the preset crystal parameter input by the user via the interface 600. When a preset crystal growth coefficient is input via the interface 700, the user may further adjust the preset crystal parameter. Referring to FIG. 5, the preset crystal growth parameter may include a preset crystal growth speed (e.g., preset crystal growth speeds corresponding to different crystal growth stages), a preset growth coefficient (e.g., proportional terms and/or integral terms corresponding to different crystal growth stages), a preset rotation crystal speed (e.g., preset rotation crystal speeds corresponding to different crystal growth stages), or the like, or any combination thereof.

In some embodiments, after the preset crystal growth parameter is input by the user, the processing device and/or the control device may construct a final crystal growth model based on the preliminary crystal growth model. As described elsewhere in the present disclosure, the processing device and/or the control device may control the entire crystal growth process based on the crystal growth model.

FIG. 8 is a flowchart illustrating an exemplary process for determining a temperature control parameter according to some embodiments of the present disclosure. In some embodiments, process 800 may be performed by a processing device (e.g., the processing device 101) and/or a control device (e.g., the control device 102). For example, process 800 may be stored in a storage device (e.g., a storage device, a storage unit of the processing device and/or the control device) in a form of programs or instructions. When the processor 202 or the modules shown in FIG. 3 execute the programs or instructions, process 800 may be implemented. In some embodiments, process 800 may be accomplished with one or more additional operations not described, and/or without one or more of the operations discussed. Additionally, the order of the operations as illustrated in FIG. 8 is not intended to be limiting.

In 801, a difference between an actual crystal parameter and a reference crystal parameter may be determined. In some embodiments, operation 801 may be executed by the determination module 302.

As described in connection with FIG. 5, the actual crystal parameter may include an actual crystal mass, an actual crystal diameter, an actual crystal height, an actual crystal shape, or the like, or any combination thereof. The reference crystal parameter may include a reference crystal mass, a reference crystal diameter, a reference crystal height, a reference crystal shape, or the like, or any combination thereof.

In some embodiments, the difference between the actual crystal parameter and the reference crystal parameter may include a difference between the actual crystal mass and the reference crystal mass. For example, if the actual crystal mass is m₁ and the reference crystal mass is m₂, the difference between the actual crystal mass and the reference crystal mass may be an absolute value of the difference between the two (i.e., |m₁−m₂|).

In some embodiments, the difference between the actual crystal parameter and the reference crystal parameter may include a difference between the actual crystal diameter and the reference crystal diameter. For example, if the actual crystal diameter is d₁ and the reference crystal diameter is d₂, the difference between the actual crystal diameter and the reference crystal diameter may be an absolute value of the difference between the two (i.e., |d₁−d₂|).

In some embodiments, the difference between the actual crystal parameter and the reference crystal parameter may include a difference between the actual crystal height and the reference crystal height, a difference between the actual crystal shape and the reference crystal shape, or the like, the descriptions of which are not repeated here.

In some embodiments, the difference between the actual crystal parameter and the reference crystal parameter may be reflected in a form of a numerical value, a formula, a vector, a matrix, a text, an image, etc.

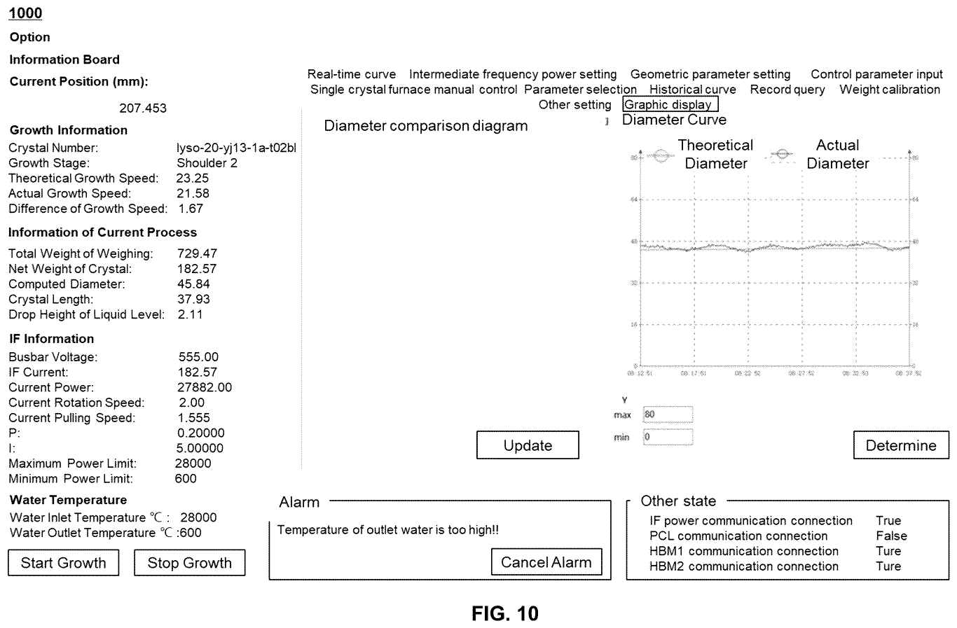

In some embodiments, the processing device and/or the control device may display the difference between the actual crystal parameter and the reference crystal parameter via an interface (e.g., an interface 1000). For example, as shown in FIG. 10, the processing device and/or the control device may display the difference between the actual crystal diameter and the reference crystal diameter in a form of a graph via the interface 1000.

In 802, a temperature control parameter may be determined based on the difference and a preset reference crystal growth parameter. In some embodiments, operation 802 may be executed by the determination module 302.

In some embodiments, referring to FIG. 4 and FIG. 5, the processing device and/or the control device may determine the reference crystal growth parameter corresponding to a target time slice. For example, the processing device and/or the control device may determine the reference crystal growth parameter corresponding to the target time slice based on a crystal growth model. In some embodiments, the reference crystal growth parameter may include a reference growth coefficient, a reference growth speed, or the like, or any combination thereof. In some embodiments, the reference growth coefficient may include a proportional term, an integral term, or the like.

In some embodiments, as described elsewhere in the present disclosure, when constructing the crystal growth model, the processing device and/or the control device may consider a factor such as a continuity of different crystal growth stages. Accordingly, the reference crystal growth parameter determined based on the crystal growth model may also satisfy a continuity requirement. That is, the reference crystal growth parameters at different moments or between different time slices may be continuous or gradual. For example, if a proportional term of an equal diameter stage 1 is 2, a proportional term of an equal diameter stage 2 is 5, and a duration of the equal diameter stage 1 is 1 hour, a change speed of the proportional term in the equal diameter stage 1 may be 0.05/minute (i.e., continuously changes from 2 to 5).

In some embodiments, the temperature control parameter may be used to control a temperature of a furnace in the crystal growth device. Specifically, the temperature control parameter may include a change of a heating parameter (e.g., a power change of an intermediate frequency power supply, a current change of the intermediate frequency power supply, a power change of an induction coil, a current change of the induction coil) used to control a heating component (e.g., the intermediate frequency power supply, the induction coil). More descriptions of the temperature control parameter may be found in the description of operation 403, which are not repeated here.

Merely by way of example, the determination module 302 may determine the temperature control parameter according to formula (4):

$$W = P \times Δ e + \frac{\int Δ e dt}{I} , \qquad ( 4 )$$

wherein W represents a temperature control parameter; Ae represents a difference between an actual crystal mass and a reference crystal mass (or a difference between an actual crystal diameter and a reference crystal diameter); P represents a proportional term; I represents an integral term; dt represents a duration of a target time slice.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, the reference crystal growth parameter may be a system default value, a user-defined value, etc., instead of determined by the crystal growth model. It should be understood that the reference crystal growth parameter determined by any method should also satisfy the continuity requirement.

FIG. 9 is a flowchart illustrating an exemplary process for determining a pulling control parameter according to some embodiments of the present disclosure. In some embodiments, process 900 may be performed by a processing device (e.g., the processing device 101) and/or a control device (e.g., the control device 102). For example, process 900 may be stored in a storage device (e.g., a storage device, a storage unit of the processing device and/or the control device) in a form of programs or instructions. When the processor 202 or the modules shown in FIG. 3 execute the program or instruction, process 900 may be implemented. In some embodiments, process 900 may be accomplished with one or more additional operations not described, and/or without one or more of the operations discussed. Additionally, the order of the operations as illustrated in FIG. 9 is not intended to be limiting.

In 901, a drop speed of a liquid level in a target time slice may be determined based on an actual crystal mass, a melting density of a raw material, and a size of a chamber. Specifically, the operation may be executed by the determination module 302.

In some embodiments, in combination with formula (1), the processing device and/or the control device may determine the drop height of the liquid level in the target time slice based on the actual crystal mass, the melting density of the raw material, and the size of the chamber. In some embodiments, in combination with formula (2), the processing device and/or the control device may determine the drop height of the liquid level in the target time slice based on the actual crystal mass, the melting density of the raw material, the size of the chamber, and a feeding mass of raw material in the target time slice.

Further, the processing device and/or the control device may determine the drop speed of the liquid level in the target time slice based on the drop height of the liquid level and the duration of the target time slice. For example, the drop speed of the liquid level in the target time slice=the drop height of the liquid level in the target time slice/the duration of the target time slice.

In 902, a pulling control parameter may be determined based on the drop speed of the liquid level and a reference crystal growth parameter. Specifically, the operation may be executed by the determination module 302.

In some embodiments, referring to FIG. 4 and FIG. 5, the processing device and/or the control device may determine the reference crystal growth parameter corresponding to the target time slice. For example, the processing device and/or the control device may determine the reference crystal growth parameter corresponding to the target time slice based on the crystal growth model. In some embodiments, the reference crystal growth parameter may include a reference growth coefficient, a reference growth speed, or the like, or any combination thereof.

In some embodiments, the pulling control parameter may be used to control a pulling process of a pulling component (e.g., a pulling motor) in the crystal growth device. Specifically, the pulling control parameter may include a parameter for controlling a change of the pulling parameter of the pulling component (e.g., a change of a rotation speed of the pulling motor, a change of a power of the pulling motor). More descriptions regarding the pulling control parameter may be found in the description of operation 404, which are not repeated here.

In some embodiments, the determination module 302 may determine the pulling control parameter based on formula (5):

$$Δ P = a * ( {v}_{r} - {v}_{l} ) - {P}_{c} , \qquad ( 5 )$$

wherein ΔP represents a pulling control parameter; a represents a conversion coefficient between a rotation speed (or power) of a pulling motor and a pulling speed; vᵣ represents a reference growth speed; vₗ represents a drop speed of a liquid level; P_{c} represents a rotation speed (or power) of a pulling motor corresponding to a target time slice.

In some embodiments, the processing device and/or the control device may determine or adjust the pulling control parameter based on the difference between the actual crystal parameter and the reference crystal parameter (e.g., a difference between the actual crystal mass and the reference crystal mass, a difference between the actual crystal diameter and the reference crystal diameter). For example, if the difference between the actual crystal mass and the reference crystal mass is greater than a preset threshold, the processing device and/or the control device may increase the pulling control parameter.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

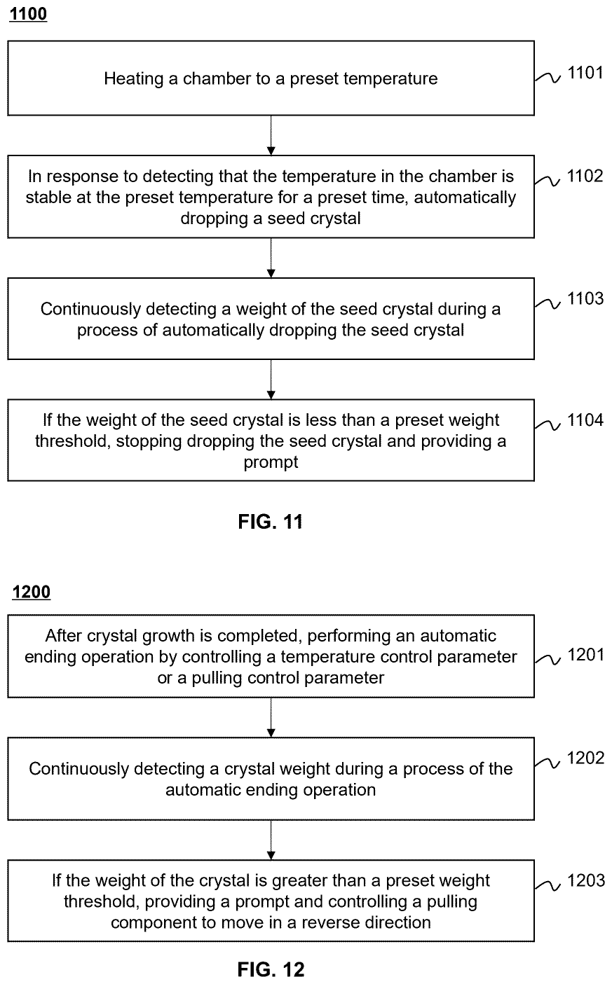

FIG. 11 is a flowchart illustrating an exemplary process for controlling a drop of a seed crystal according to some embodiments of the present disclosure. In some embodiments, process 1100 may be performed by a processing device (e.g., the processing device 101) and/or a control device (e.g., the control device 102). For example, process 1100 may be stored in a storage device (e.g., a storage device, a storage unit of the processing device and/or the control device) in a form of programs or instructions. When the processor 202 or the modules shown in FIG. 3 execute the program or instruction, process 1100 may be implemented. In some embodiments, the process 1100 may be accomplished with one or more additional operations not described, and/or without one or more of the operations discussed. Additionally, the order of the operations as illustrated in FIG. 11 is not intended to be limiting.

In 1101, a chamber may be heated to a preset temperature. In some embodiments, operation 1101 may be executed by the control module 303.

In some embodiments, the preset temperature may be a melting temperature of a raw material, a temperature at which a crystal starts to grow, or any temperature value between the melting temperature of the raw material and the temperature at which the crystal starts to grow. In some embodiments, the preset temperature may be a system default value. Alternatively, the preset temperature may be set by a user in combination with an actual requirement. In some embodiments, different crystal types may correspond to different preset temperatures. In some embodiments, different crystal growth parameters (e.g., a crystal shape, a crystal height, a crystal diameter) may correspond to different preset temperatures. In some embodiments, different chambers (e.g., chambers with different shapes, different sizes, different thermal conductivities) may correspond to different preset temperatures.

In some embodiments, the processing device and/or the control device may heat the chamber via a heating component (e.g., the heating component 106). In some embodiments, a temperature sensor may be provided in the chamber. When the temperature sensor senses that a temperature in the chamber reaches the preset temperature, the processing device and/or the control device may provide a prompt (e.g., provide a prompt such as a voice or a buzzer) via a prompting device.

In 1102, in response to detecting that the temperature in the chamber is stable at the preset temperature for a preset time, a seed crystal may be automatically dropped. In some embodiments, operation 1102 may be executed by the control module 303.

In some embodiments, the preset time may be a system default value, or may be adjusted according to different situations. For example, the preset time may be 5 minutes, 10 minutes, 20 minutes, 30 minutes, 40 minutes, 1 hour, 1.5 hours, etc.

In some embodiments, different crystal types may correspond to different preset times. In some embodiments, different crystal growth parameters (e.g., the crystal shape, the crystal height, the crystal diameter) may correspond to different preset times. In some embodiments, different chambers (e.g., chambers with different shapes, different sizes, different thermal conductivities) may correspond to different preset times. The preset time only needs to ensure that the raw material can be completely melted and may be set according to an actual requirement, which may not be limited in the present disclosure.

In some embodiments, the processing device and/or the control device may control a movement of a pulling motor to slowly drop the seed crystal. In some embodiments, a drop speed of the seed crystal may be a system default value or may be adjusted according to different situations.

In 1103, a weight of the seed crystal may be continuously detected during a process of automatically dropping the seed crystal. In some embodiments, operation 1103 may be executed by the control module 303.

In some embodiments, during the process of dropping the seed crystal, the processing device and/or the control device may monitor the weight of the seed crystal in real time via a weighing component (e.g., the crystal weighing component 105).

In 1104, if the weight of the seed crystal is less than a preset weight threshold, the dropping of the seed crystal may be stopped and a prompt may be provided. In some embodiments, operation 1104 may be executed by the control module 303.

During the continuous dropping of the seed crystal, after the seed crystal contacts the liquid level of the raw material, a bottom end of the seed crystal may be melted and the weight of the seed crystal may be reduced. Subsequently, the processing device and/or the control device may continue to slowly drop the seed crystal in the molten raw material. In this process, the weight of the seed crystal may gradually decrease. The processing device and/or the control device may continuously monitor the weight of the seed crystal. When it is detected that the weight of the seed crystal is less than the preset weight threshold (or a sudden decrease of the weight of the seed crystal (e.g., a weight difference between a current moment and a previous moment) is greater than a preset weight difference threshold), it may indicate that the seed crystal hits a wall of the chamber at the current moment. The processing device and/or the control device may provide the prompt. For example, the processing device and/or the control device may provide the prompt by providing the voice or the buzzer.

In some embodiments, the preset weight threshold may be a minimum weight of the seed crystal after the seed crystal contacts the liquid level of the raw material and is melted. The preset weight difference threshold may be a maximum weight that the seed crystal can reduce between adjacent moments. In some embodiments, the preset weight threshold and/or the preset weight difference threshold may be system default values or may be adjusted according to different situations. For example, the preset weight threshold may be 0.8 times or 0.7 times the weight of the seed crystal. As another example, the preset weight difference threshold may be 1 gram, 2 grams, etc.

In some embodiments, the processing device and/or the control device may also obtain a real-time image of the inside of the chamber (e.g., an image of the seed crystal captured by an infrared high-definition camera) during the process of dropping the seed crystal. The real-time image may be compared with a preset reference image. A determination may be made as to whether to adjust a heating parameter (e.g., a parameter of the heating component 106) based on a comparison result. In some embodiments, the preset reference image may be an image at each time point when the seed crystal is theoretically normally melted.

Specifically, when the seed crystal contacts the liquid level of the raw material, for example, the real-time image shows that the seed crystal forms a meniscus with the liquid of the raw material, or when the weight of the seed crystal fluctuates within a preset range (e.g., a sudden increase or a sudden decrease of 1-2 grams), the processing device and/or the control device may compare (e.g., determine a similarity) relevant information in the real-time image (e.g., a size, a brightness of the meniscus, a size of a meniscus aperture, a flow range of a flow line of the raw material liquid) with corresponding information in the preset reference image. A determination may be made as to whether to adjust the heating parameter based on the comparison result. For example, if the similarity is greater than a preset similarity threshold, it may be determined that there is no need to adjust the heating parameter. If the similarity is less than or equal to the preset similarity threshold, the heating parameter may need to be adjusted.

In some embodiments, the processing device and/or the control device may divide the preset reference image and the real-time image into a plurality of corresponding regions, respectively. For each region, the processing device and/or the control device may compare (e.g., determine a similarity) real-time image information with corresponding preset reference image information. When comparison results of two or more regions satisfy a requirement, the temperature in the chamber may be considered appropriate, and there is no need to adjust the heating parameter.

In some embodiments, the processing device and/or the control device may preset a length of the seed crystal that needs to be melted after the seed crystal contacts the liquid of the raw material. When it is detected that a melting length of the seed crystal satisfies a requirement (e.g., 20-40 minutes after the melting is completed), the processing device and/or the control device may compare the temperature in the chamber again. If the temperature in the chamber is appropriate at this time, the chamber then enters a constant temperature state, and an inoculation of the seed crystal is completed.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, the preset range of the weight fluctuation of the seed crystal may be set according to an actual requirement, for example, 0.5 grams, 3 grams, 5 grams, etc. As another example, the real-time image of the seed crystal may be acquired by any image acquisition device.

FIG. 12 is a flowchart illustrating an exemplary process of an automatic ending operation according to some embodiments of the present disclosure. In some embodiments, process 1200 may be performed by a processing device (e.g., the processing device 101) and/or a control device (e.g., the control device 102). For example, process 1200 may be stored in a storage device (e.g., a storage device, a storage unit of the processing device and/or the control device) in a form of programs or instructions. When the processor 202 or the modules shown in FIG. 3 execute the programs or instructions, process 1200 may be implemented. In some embodiments, process 1200 may be accomplished with one or more additional operations not described, and/or without one or more of the operations discussed. Additionally, the order of the operations as illustrated in FIG. 12 is not intended to be limiting.

In 1201, after the crystal growth is completed, an automatic ending operation may be performed by controlling a temperature control parameter or a pulling control parameter. In some embodiments, operation 1201 may be executed by the control module 303.

In some embodiments, during the automatic ending operation, the processing device and/or the control device may control an automatic ending of the crystal by controlling the temperature control parameter (e.g., controlling a power or a current of an induction coil) or the pulling control parameter (e.g., controlling a power of a pulling component). Specifically, after the crystal growth is completed, the processing device and/or the control device may control a pulling motor to pull the crystal upward to a preset height at a preset pulling speed, so that a bottom of the crystal is at a certain height (e.g., 5 centimeters, 10 centimeters, 20 centimeters, 30 centimeters) from a liquid level of the raw material. When the crystal is pulled to the preset height, the processing device and/or the control device may control a current or a power of an intermediate frequency power supply to gradually decrease, so that a temperature in the chamber may gradually decrease.

In some embodiments, the preset pulling speed or the preset height may be a system default value or may be adjusted according to different situations. For example, during the pulling process, as the crystal gradually leaves the raw material liquid, a structural stress may appear inside the crystal due to a sudden drop in temperature. The processing device and/or the control device may adjust the preset pulling speed according to the internal structural stress, so as to ensure that the crystal do not crack due to the internal structural stress. For example, the pulling speed may be 1-10 millimeters/hour.

In 1202, a crystal weight may be continuously detected during the automatic ending operation. In some embodiments, operation 1202 may be executed by the control module 303.

In some embodiments, during the pulling process, the processing device and/or the control device may monitor the crystal weight in real time via a weighing component (e.g., the crystal weighing component 105).

In 1203, if the weight of the crystal is greater than a preset weight threshold, a prompt may be provided and a pulling component may be controlled to move in a reverse direction. In some embodiments, operation 1203 may be executed by the control module 303.

During the pulling process, the processing device and/or the control device may continuously monitor the crystal weight. When it is detected that the crystal weight is greater than the preset weight threshold (or a sudden increase in the crystal weight (e.g., the weight difference between a current moment and a previous moment) is greater than a preset weight difference threshold), it may indicate that the crystal is bonded to the wall of the chamber at the current moment. The processing device and/or the control device may provide a prompt and control the pulling component to move in a reverse direction, thereby reducing a tensile force at the bond between the crystal and the chamber, and reducing a chance of crystal cracking.

In some embodiments, the preset weight threshold may be greater than the crystal weight after the crystal is completely separated from the raw material liquid. The preset weight difference threshold may be the maximum weight that the crystal can increase between adjacent moments. In some embodiments, the preset weight threshold and/or the preset weight difference threshold may be system default values or may be adjusted according to different situations. For example, if the weight of the crystal after it is completely separated from the raw material liquid is 20 kilograms, the preset weight threshold may be set as 21 kilograms, 22 kilograms, etc.

In some embodiments, the processing device and/or the control device may control the pulling component (e.g., the pulling motor) to move in a reverse direction until the crystal weight is less than the preset weight threshold. At this time, the crystal may be pulled upward again. When the crystal weight is greater than the preset weight threshold again, the pulling component may be controlled to move in the reverse direction again, and repeated several times, until the crystal weight is continuously less than the preset weight threshold, which may indicate that the crystal is pulled off the wall of the chamber.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure.

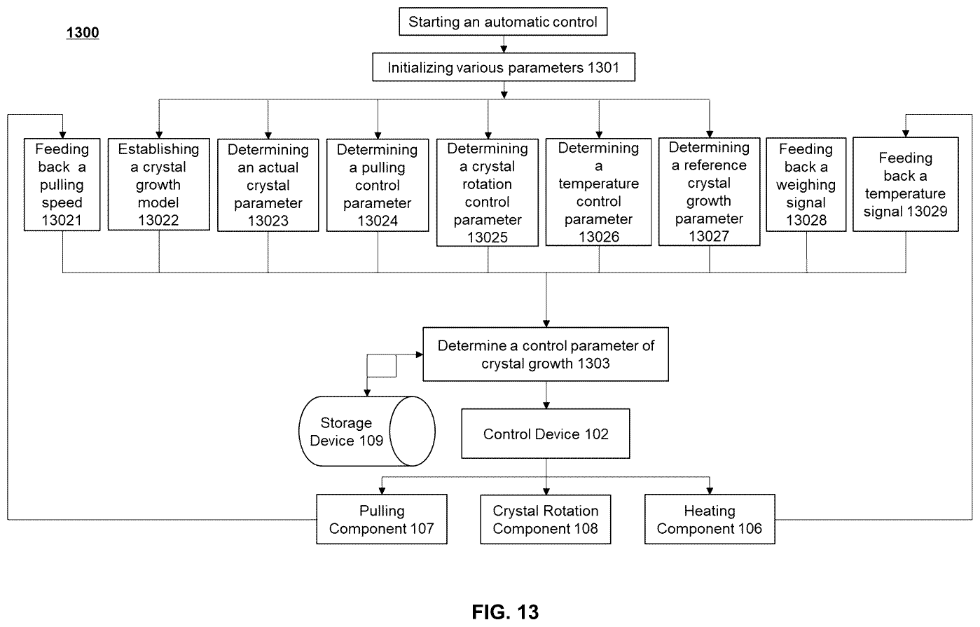

FIG. 13 is a schematic diagram illustrating an exemplary process for controlling crystal growth according to some embodiments of the present disclosure.

In a crystal preparation process, after a seed crystal contacts a liquid level of a raw material and is melted, when a weight of the seed crystal is less than a preset weight threshold, a crystal growth stage may be started after the seed crystal keeps stable for a time period. In some embodiments, the processing device and/or the control device may control the crystal growth in an automatic control manner (e.g., start an automatic control).

After the automatic control is started, operation 1301 may be executed to initialize various parameters. The initialization may delete historical data not related to the crystal preparation. After the initialization is completed, the crystal growth control system 100 may execute the following operations:

In 13022, the processing device 101 may establish a crystal growth model. The processing device 101 may also determine a reference crystal parameter and/or a reference crystal growth parameter based on the crystal growth model. More descriptions regarding the crystal growth model may be found in FIGS. 5-7 and the descriptions thereof, which are not repeated here.

In 13023, the processing device 101 may determine an actual crystal parameter. Specifically, the processing device 101 may obtain an actual crystal mass in real time via the crystal weighing component 105. The processing device 101 may also determine an actual crystal height and an actual crystal diameter in each time slice in real time.

In 13024, the processing device 101 may determine a pulling control parameter. More descriptions regarding the pulling control parameter may be found in FIGS. 4-9 and the descriptions thereof, which are not repeated here.

In 13025, the processing device 101 may determine a crystal rotation control parameter. Specifically, the processing device 101 may determine the crystal rotation control parameter corresponding to a specific time slice according to the reference crystal parameter and/or the reference crystal growth parameter corresponding to the specific time slice, and then adjust a crystal rotation speed in a next time slice based on the crystal rotation control parameter.

In 13026, the processing device 101 may determine a temperature control parameter.

In 13027, the processing device 101 may determine a reference crystal growth parameter (e.g., a reference growth coefficient). In some embodiments, operation 13026 may be combined in operation 13022. That is, the processing device 101 may determine the reference crystal growth coefficient based on the crystal growth model. In some embodiments, the processing device 101 may also determine the reference crystal growth coefficient separately, that is, it is unnecessary to determine the reference crystal growth coefficient through the crystal growth model. More descriptions regarding the reference crystal growth parameter may be found in FIGS. 4-7 and the descriptions thereof, which are not repeated here.

In 13021, the pulling component 107 may feedback a current speed to the processing device 101. In some embodiments, the processing device 101 may read a pulling height of the crystal via a grating ruler, or determine the pulling height according to a rotation speed of the pulling motor, and then determine a pulling speed.

In 13028, the crystal weighing component 105 may feedback a weighing signal to the processing device 101. The processing device 101 may determine the actual crystal mass based on the weighing signal. In some embodiments, operation 13027 may be combined in operation 13023. That is, the processing device 101 may determine the actual crystal parameter based on the weighing signal.

In 13029, the heating component 106 may feedback a current temperature signal to the processing device 101. The processing device 101 may determine a temperature value based on the temperature signal.

In 1303, the processing device 101 may determine a control parameter of crystal growth (e.g., a pulling control parameter, a crystal rotation control parameter, a temperature control parameter) based on the relevant data of the above operations 13021 to 13029. Further, the processing device 101 may transmit various control parameters to the control device 102. The control device 102 may control a subsequent process. Specifically, the control device 102 may control a pulling process of the pulling component 107 based on the pulling control parameter. The control device 102 may control a heating process of the heating component 106 based on the temperature control parameter. The control device 102 may control a crystal rotation process of the crystal rotation component 108 based on the crystal rotation control parameter.

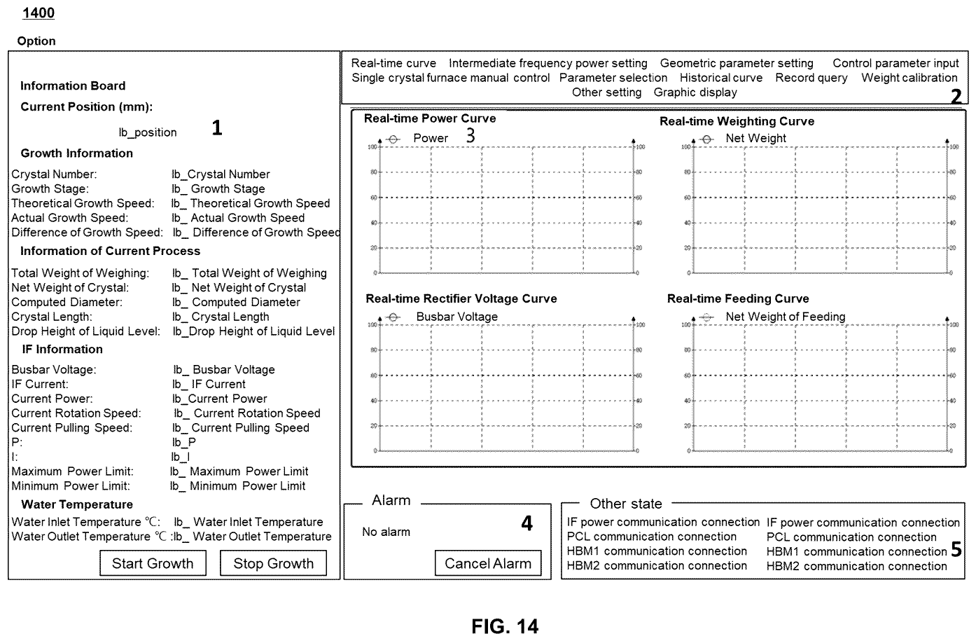

FIG. 14 is an exemplary operation interface illustrating an exemplary crystal growth control system according to some embodiments of the present disclosure.

As shown in FIG. 14, an operation interface 1400 may be divided into 5 major functional areas: (1) a crystal growth information display area (located on a left side of the operation interface 1400) used to observe real-time data of a crystal growth process, such as a growth stage, a crystal weight, information of an intermediate frequency power supply, etc.; (2) a functional module switching button area (located at a top of the operation interface 1400) used to switch between various sub-functional modules (e.g., a real-time curve, an intermediate frequency power setting, a record query, etc.); (3) a sub-function module display area (located in a middle of the operation interface 1400) used to display contents of each sub-function module; (4) an alarm area (located in a lower middle part of the operation interface 1400) used to display an alarm content of a current system and prompt an operator to perform a corresponding processing for the alarm; (5) a communication status display area (located on a lower right part of the operation interface 1400) used to display a communication status of a device or a module in real time, for example, an intermediate frequency power communication connection, a PCL communication connection, etc.

It should be noted that the above description of the process is merely provided for the purposes of illustration, and not intended to limit the scope of the present disclosure. For persons having ordinary skills in the art, multiple variations and modifications may be made under the teachings of the present disclosure. However, those variations and modifications do not depart from the scope of the present disclosure. For example, the operation interface may also include other functional areas, such as a crystal real-time shape area.

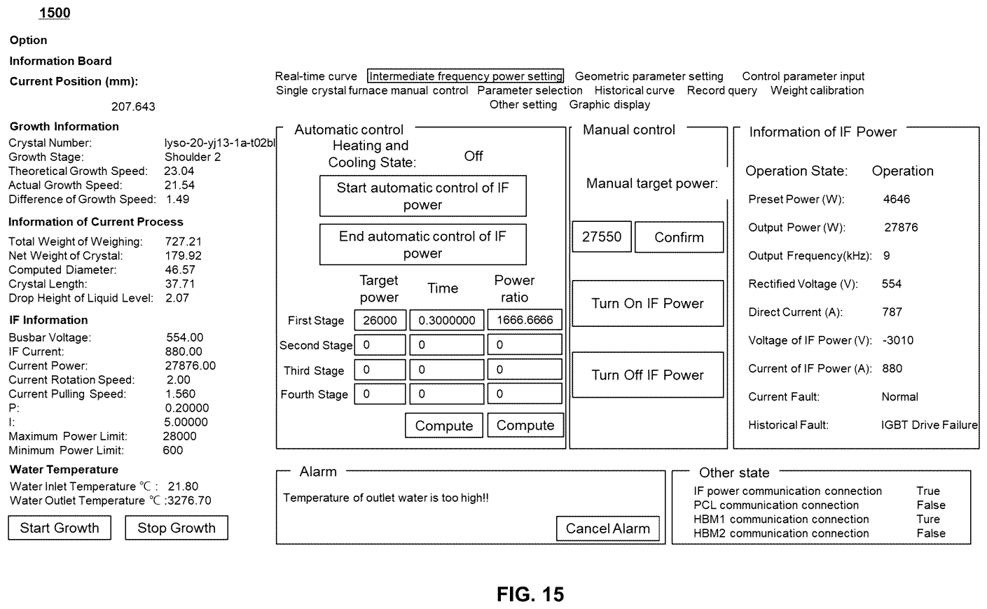

FIG. 15 is an exemplary operation interface for an intermediate frequency power control according to some embodiments of the present disclosure.

Referring to FIG. 5 and FIG. 8, the processing device and/or control device may adjust a temperature in any time slice based on a temperature control parameter. For example, the processing device and/or control device may adjust a parameter of a heating component (e.g., an intermediate frequency power supply, an induction coil) based on the temperature control parameter via an automatic control. As shown in FIG. 15, an operation interface 1500 may display a specific control condition of the intermediate frequency power supply, for example, a target power, time, a power ratio, etc. In some embodiments, the automatic control may be used in a middle stage and a late stage of the crystal growth (e.g., a shouldering stage, an equal diameter stage, an ending stage).

In some embodiments, a parameter of the intermediate frequency power supply may also be controlled via a manual control manner. The manual control may be used in an early stage of the crystal growth (e.g., a process of dropping a seed crystal, a process of heating a chamber). For example, as shown in FIG. 15, the intermediate frequency power supply may be switched by pressing buttons “turn on intermediate frequency power” and “turn off intermediate frequency power.” The operation interface 1500 may also display specific information of the intermediate frequency power supply, such as an operating status, a setting power, an output power, etc.

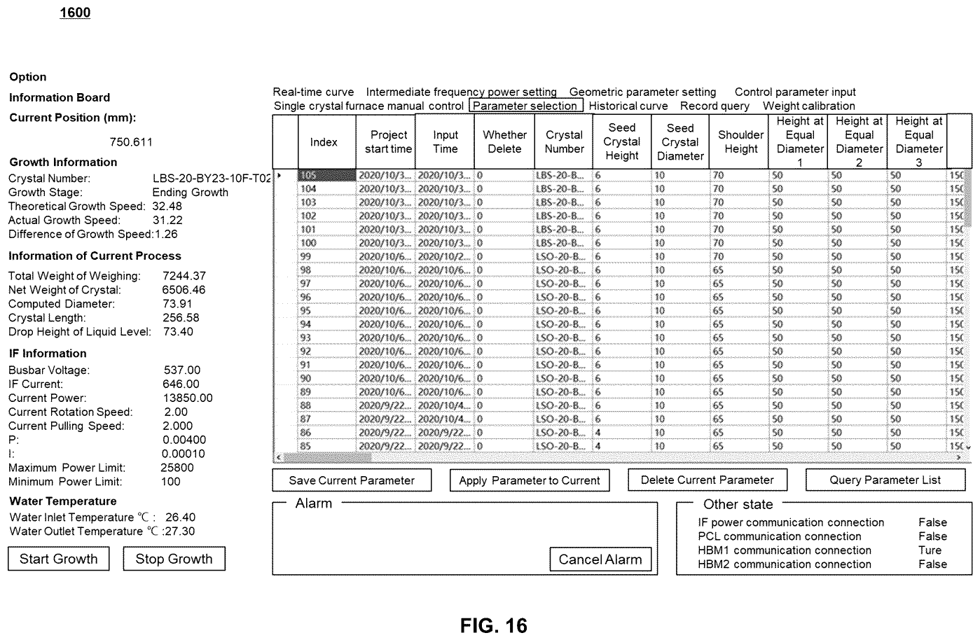

FIG. 16 is an exemplary operation interface for a parameter selection according to some embodiments of the present disclosure.

In some embodiments, the crystal growth control system 100 may have a parameter selection function. As shown in FIG. 16, a user may query, via an operation interface 1600, parameters that have been run, for example, an actual crystal growth parameter (e.g., a crystal growth temperature, a pulling speed, a crystal rotation speed), a reference crystal parameter (e.g., a reference crystal mass, a reference crystal diameter, a reference crystal height), a reference crystal growth parameter (e.g., a reference growth coefficient, a reference pulling speed). Further, the user may also select a parameter via the operation interface 1600. After the parameter is selected, the selected parameter may be saved (i.e., “save current parameter”), the selected parameter may be applied to a current crystal growth process (i.e., “apply parameter to current process”), the selected parameter may be deleted (i.e., “delete current parameter”), or details of the selected parameter may be queried (i.e., “query parameter list”), or the like.

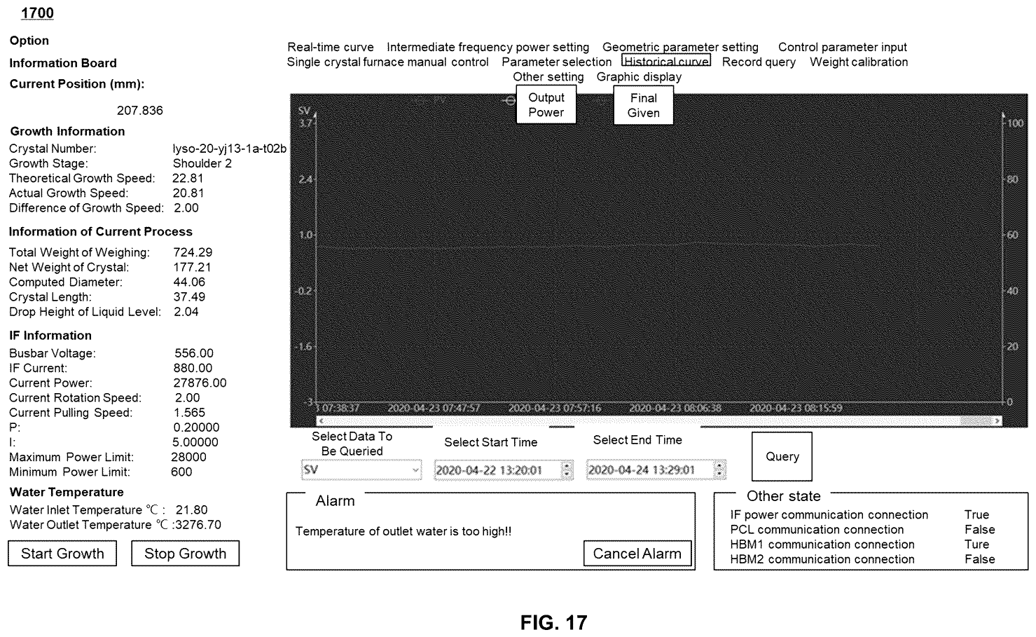

FIG. 17 is an exemplary operation interface for a historical curve query according to some embodiments of the present disclosure.

In some embodiments, the crystal growth control system 100 may have a historical curve query function. As shown in FIG. 17, an operation interface 1700 may display a historical curve. The horizontal axis represents time and the vertical axis represents historical target data. In some embodiments, the historical target data may be crystal growth data (e.g., an actual crystal height, an actual crystal diameter, a growth speed, a growth stage, an actual crystal mass), a control parameter (e.g., a crystal rotation speed, a pulling speed, a temperature), etc. As shown in FIG. 17, a user may input a time period to be queried (i.e., “select start time” and “select end time”) via the operation interface 1700, input historical target data to be queried (i.e., “select data to be queried”), and click a “query” button to query the historical target data in the time period. A display area of the operation interface 1700 may display a historical curve of the historical target data within the time period. The user can intuitively view a data trend and then determine a growth status of the crystal. Further, the user may query a plurality of types of historical target data in the same time period simultaneously. For example, the user may input the actual crystal diameter, the actual crystal height, and the pulling speed in the operation interface 1700 simultaneously. The display area may display historical curves of the above three parameters simultaneously, which may be easy for the user to view.

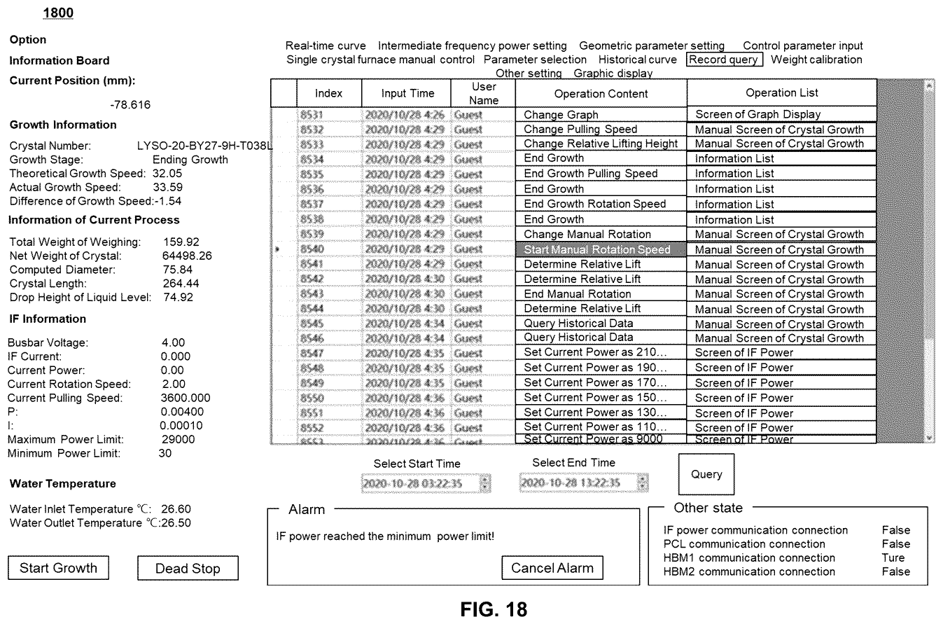

FIG. 18 is an exemplary operation interface for an operation record query according to some embodiments of the present disclosure.

In some embodiments, the crystal growth control system 100 may have an operation record query function. As shown in FIG. 18, a user may input a time period to be queried (i.e., “select start time” and “select end time”) via an operation interface 1800. Then, operation records in the time period may be queried and displayed in a table on the operation interface 1800.

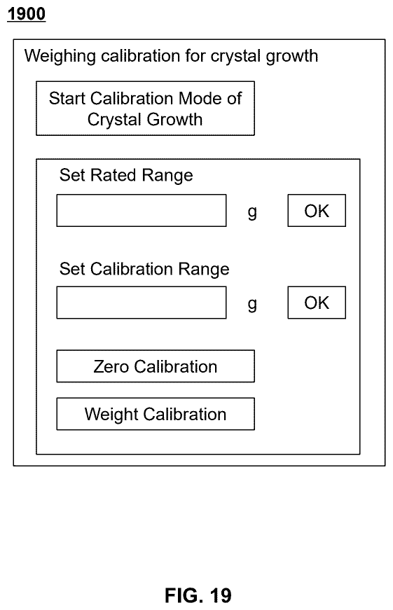

FIG. 19 is an exemplary operation interface for a weighing calibration according to some embodiments of the present disclosure.

In some embodiments, the crystal growth control system 100 may have a weighing calibration function. In some cases, a weighing component (e.g., the feeding and weighing component 104, the crystal weighing component 105) may have certain errors after a time period of use and need to be calibrated, or after the weighing component is replaced, the weighing component may also need to be calibrated. In some embodiments, as shown in FIG. 19, a zero calibration operation and a weight calibration operation may be performed on the weighing component. A zero setting may be performed on the weighing component through the zero calibration. An accuracy of the weighing component may be adjusted through the weight calibration operation. As shown in FIG. 19, a user may click a button “zero calibration,” input a rated range and a calibration range, and click a button “weight calibration” on the operation interface 1900, to calibrate the weighing component (i.e., “start calibration mode of crystal growth”). Specifically, when the weighing component is not executing a weighting operation, the weighing component may be reset to zero by clicking the button “zero calibration;” a maximum range of the weighing component may be input in “set rated range” and a button “OK” may be clicked to set; subsequently, a standard weight may be placed on the weighing component, a weight of the standard weight may be input in “set calibration range,” and the button “OK” may be clicked to set; finally, the button “weight calibration” may be clicked. The processing device 101 may send the calibration range to the weighing component and calibrate the weighing component according to a value (e.g., the weight of the standard weight) obtained from the weighing component. In some embodiments, the weighting component may be calibrated by a plurality of standard weights with different weights. In some embodiments, the zero calibration, the rated range, the calibration range, and deformation data of the weighing component input during the calibration process may be stored in the corresponding weighing component.

It should be noted that the above description of the process is merely provided for the purposes of illustration, and not intended to limit the scope of the present disclosure. For persons having ordinary skills in the art, multiple variations and modifications in form and detail to the implementation of the above processes and systems, devices, and equipment may be made under the teachings of the present disclosure. However, those variations and modifications do not depart from the scope of the present disclosure.

With the development of science and technology, crystals (e.g., silicon carbide) are widely used in various optoelectronic devices and electronic devices. As the demand for crystals gradually increases, how to improve the quality of crystal growth has become a focus of attention in the field.

During the process of crystal growth, the crystal face temperature is the core factor of the crystal growth quality. However, it is difficult to observe the crystal face temperature during the process of crystal growth, resulting in the inability to accurately control the crystal face temperature during the process of crystal growth, and the low crystal growth quality. Therefore, how to improve the quality of crystal growth is an urgent technical problem that needs to be solved in this field.

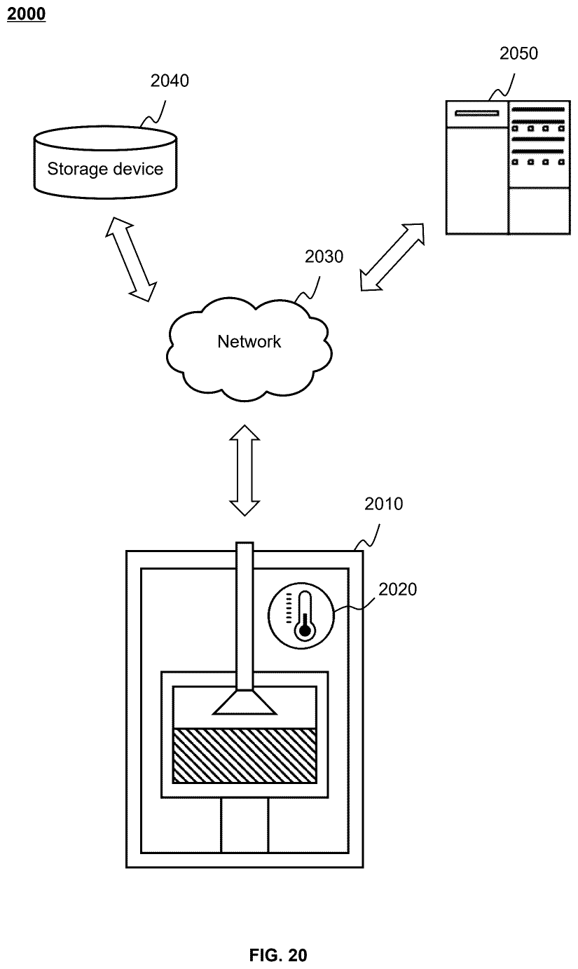

FIG. 20 is a schematic diagram illustrating an application scenario of a crystal growth system according to some embodiments of the present disclosure.

As shown in FIG. 20, an application scenario 2000 of the crystal growth system may include a crystal growth device 2010, a temperature measurement device 2020, a network 2030, a storage device 2040, and a processor 2050.

The crystal growth device 2010 is a device for crystal growth. The crystal may include but is not limited to silicon carbide, germanium single crystal, and so on. The crystal growth device 2010 may include but is not limited to a physical vapor transport crystal growth device, a liquid phase epitaxy crystal growth device, a Czochralski crystal growth device, and so on. The crystal growth device 2010 may include structures such as a furnace body, a crucible, a heat insulation layer, and a seed crystal holder. It is understood that any of crystal growth method can determine the crystal face temperature during the crystal growth process by the crystal growth method as shown in any embodiment of the present disclosure to complete crystal growth.

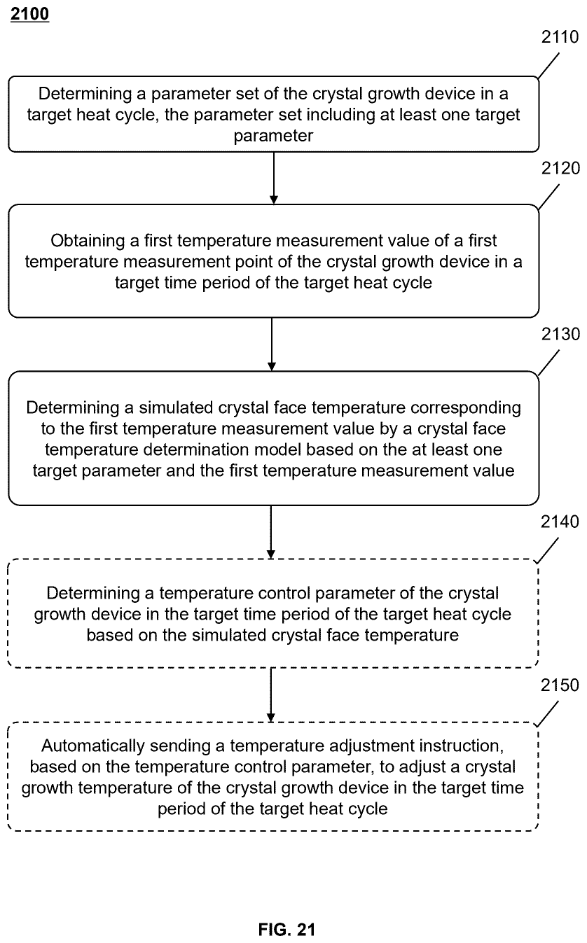

The temperature measurement device 2020 is a device for measuring temperature. The temperature measurement device 2020 may include but is not limited to an infrared thermal imager, an optical fiber temperature sensor, etc. The temperature measurement device 2020 may be arranged in the crystal growth device 2010 to obtain a first temperature measurement value of a first temperature measurement point of the crystal growth device 2010 during a target time period of a target heat cycle. More descriptions regarding the target heat cycle, the target time period, the first temperature measurement point, and the first temperature measurement value may be found in FIG. 21 and related descriptions thereof.

The network 2030 may connect components of the application scenario 2000 of the crystal growth system and/or connect an external resource. The network 2030 may enable communication between the components and between other parts to facilitate the exchange of data and/or information. For example, the processor 2050 may obtain the first temperature measurement value measured by the temperature measurement device 2020 via the network 2030. As another example, the processor 2050 may control the crystal growth device 2010 via the network 2030. The network 2030 may be any one or more of a wired network or a wireless network. For example, the network 2030 may include a cable network, an optical fiber network, a telecommunications network, the Internet, a local area network (LAN), a wide area network (WAN), a wireless local area network, a metropolitan area network, a public switched telephone network, a Bluetooth network, a ZigBee network, a near-field communication, an in-device bus, an in-device line, cable connection, or the like, or any combination thereof. The network connection between various parts may be implemented in one of the above ways, or in various ways. The network may be a type of point-to-point, shared, centralized, and other topological structures or any combination thereof.

The storage device 2040 may be configured to store data and/or instructions. For example, the storage device 2040 may be configured to store historical data, device information, or the like, of the crystal growth device 2010. The storage device 2040 may include one or more storage components. Each of the one or more storage components may be an independent device or a part of another device. The storage device 2040 may include a random-access memory (RAM), a read-only memory (ROM), a mass memory, a removable memory, a volatile read-write memory, or the like, or any combination thereof. For example, the mass storage may include a magnetic disk, an optical disk, a solid-state disk, etc. In some embodiments, the storage device 2040 may be implemented on a cloud platform.

The processor 2050 may process data and/or information obtained from the external resource or a plurality of components of the application scenario 2000 of the crystal growth system. For example, the processor 2050 may determine a parameter set of the crystal growth device 2010 in a target heat cycle. The processor 2050 may execute program instructions based on the data, information, and/or processing results to implement one or more functions described in the present disclosure. For example, the processor 2050 may determine a simulated crystal face temperature corresponding to the first temperature measurement value by a crystal face temperature determination model based on at least one target parameter and the first temperature measurement value. As another example, the processor 2050 may determine a temperature control parameter of the crystal growth device 2010 in a target time period of the target heat cycle based on the simulated crystal face temperature. More descriptions regarding the above examples may be found in the present disclosure below. The processor 2050 may include one or more sub-processing devices (e.g., a single-core processing device or a multi-core processing device). Merely by way of example, the processor 2050 may include a central processing unit (CPU), an application specific integrated circuit (ASIC), an application specific instruction set processor (ASIP), a graphics processor, a physical processor, a digital signal processor, a field programmable gate array (FPGA), a programmable logic circuit, a controller, a microcontroller unit, a reduced instruction set computer (RISC), a microprocessor, or the like, or any combination thereof.

It should be noted that the application scenario 2000 of the crystal growth system is merely provided for the purposes of illustration, and not intended to limit the scope of the present disclosure. For persons having ordinary skills in the art, multiple variations and modifications in form and detail to the implementation of the above processes and systems, devices, and equipment may be made under the teachings of the present disclosure. For example, the application scenario 2000 of the crystal growth system may further include a database, an information source, etc. As another example, the application scenario 2000 of the crystal growth system may be implemented on other devices to achieve similar or different functions. However, those variations and modifications do not depart from the scope of the present disclosure.

FIG. 21 is a flowchart illustrating an exemplary crystal growth method according to some embodiments of the present disclosure. In some embodiments, a process 2100 may be performed by a crystal growth system 2600. As shown in FIG. 21, the process 2100 may include the following operations.

In 2110, a parameter set of a crystal growth device in a target heat cycle may be determined. In some embodiments, the operation 2110 may be performed by a parameter determination module 2610.

The target heat cycle refers to a current heat cycle of crystal growth of the crystal growth device (e.g., the crystal growth device 2010 shown in FIG. 20). For example, the target heat cycle may be a 20th heat cycle, which indicates the 20th heat cycle of crystal growth of the crystal growth device.

The parameter set is a set of target parameters of the crystal growth device in the target heat cycle. The parameter set may include at least one target parameter.

The at least one target parameter is a parameter of the crystal growth device that affects crystal growth. Specifically, the at least one target parameter may affect the speed of crystal growth, the quality of grown crystals, etc. In some embodiments, the at least one target parameter may include a first target parameter and a second target parameter.

The first target parameter may include a first parameter of a preset object in the crystal growth device in the target heat cycle. The preset object may include at least one of a crucible, a heat insulation felt (e.g., soft felt and/or hard felt), a raw material melt, and a protective gas (e.g., argon). The first parameter may reflect a material physical property of the preset object that is related to crystal growth.

In some embodiments, the parameter determination module 2610 may determine a type of the first parameter. It is understood that the material physical property of the preset object may include parameters of various types. For example, the material physical property of the preset object may include parameters in terms of density, optical properties, mechanical properties, thermal properties, electrical properties, and magnetic properties of the preset object. However, when some material physical properties (e.g., the mechanical property) of the preset object change, the influence on the crystal face temperature is relatively great; when some material physical properties (e.g., the thermal property) of the preset object change, the influence on the crystal face temperature is relatively small. In some embodiments, the parameter determination module 2610 may determine a parameter of the material physical property of the preset object that have a relatively great influence on the crystal face temperature when the material physical property changes as the first parameter, and measure the first target parameter in the target heat cycle of the crystal growth device according to the multiple embodiments, so as to reduce the amount of calculation and avoid the waste of computing resources. In some embodiments, the first parameter may include at least one of the parameters in terms of thermal property, electrical property, and magnetic property of the preset object. For example, the first parameter may include at least one of thermal conductivity, electrical conductivity, surface emissivity, a heat transfer coefficient, an isobaric heat capacity, and relative magnetic permeability.

In some embodiments, the parameter determination module 2610 may obtain a plurality sets of reference data. The plurality sets of reference data refer to data used to determine a type of the first parameter. Each set of the plurality sets of reference data may include a plurality of first candidate parameters and verification information corresponding to the plurality of first candidate parameters. The plurality of first candidate parameters are parameters to be determined as the first parameter based on evaluation. The plurality of first candidate parameters may include all material physical properties of the preset object or some user-specified material physical properties. Each of the plurality of first candidate parameters may reflect a material physical property of the preset object in the crystal growth device. The verification information is information used to verify the importance of the first parameter. For example, the verification information may include but is not limited to a furnace temperature, a furnace pressure, crystal growth quality, etc. The reference data may be obtained based on historical data of the crystal growth device. For example, a plurality of first candidate parameters and verification information in a certain set of reference data may be obtained by measuring the preset object in the crystal growth device in a historical heat cycle.

In some embodiments, the parameter determination module 2610 may determine the type of the first parameter by processing the plurality sets of reference data by an importance analysis model, the importance analysis model being a random forest model. For example, the parameter determination module 2610 may process the plurality sets of reference data by the importance analysis model to determine four types of the first parameter from the material physical properties of 20 preset objects, namely the surface emissivity, the heat transfer coefficient, the isobaric heat capacity, and the relative magnetic permeability.

The importance analysis model may analyze the plurality of first candidate parameters through the input verification information to determine the importance of each of the plurality of first candidate parameters, so as to determine the type of the first parameter. The importance of each of the plurality of first candidate parameters may be expressed in various ways, such as numerical value, a ratio, etc. For example, the parameter determination module 2610 may determine the type of the first candidate parameters of which the importance exceeds a preset importance threshold as the type of the first parameter. Some embodiments of the present disclosure screen the plurality of first candidate parameters by the random forest model to determine the type of the first parameter, such that the interference from the material physical properties of the preset object that have little influence on crystal growth is avoided, and the amount of calculation of the crystal growth system 2600 is reduced.

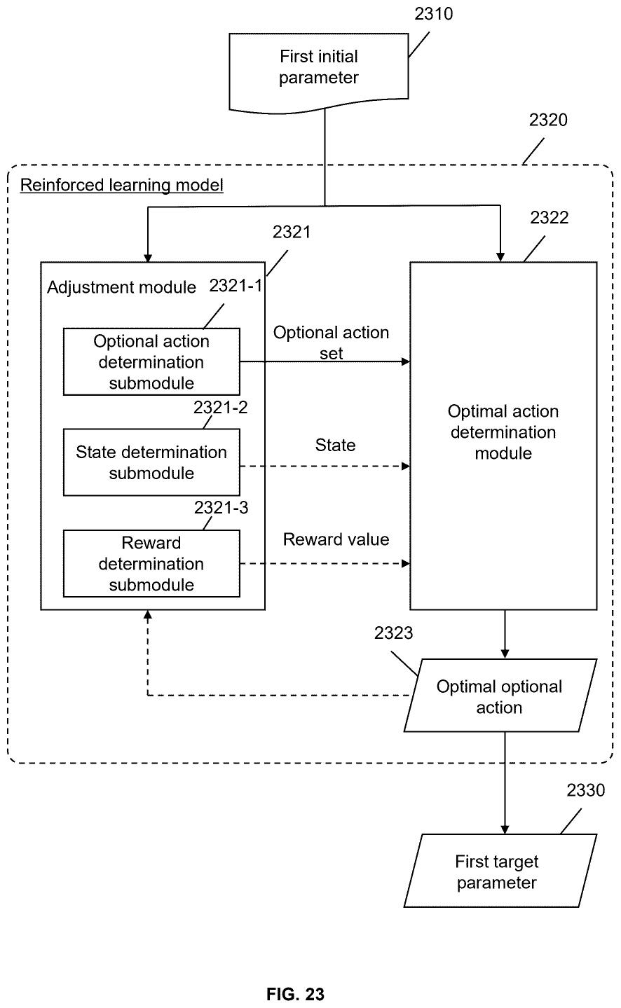

In some embodiments, the parameter determination module 2610 may determine the first target parameter of the crystal growth device in the target heat cycle based on a first initial parameter corresponding to the preset object. For example, the parameter determination module 2610 may determine the first target parameter of the crystal growth device in the target heat cycle based on device information of the crystal growth device. The device information may include relevant information of the crystal growth device. The device information may include but is not limited to a type of crystal growth device, an overall size, a size of the preset object, the first initial parameter, etc. The device information may be provided by the manufacturer of the crystal growth device. More descriptions regarding the first initial parameter may be found in FIG. 23 and related descriptions thereof.

In some embodiments, the parameter determination module 2610 may determine a specific value of the first target parameter. It should be noted that when in a room temperature state, the first parameter is relatively stable. For example, the electrical conductivity is a fixed value. However, when the crystal grow in the crystal growth device, the crystal growth device performs induction heating on the crucible by an induction coil, so the temperature of a crystal growth environment is relatively high (e.g., approx. 900-7200° C.), and in an electric field and a magnetic field, and the first parameter may change with different environments in the furnace of the crystal growth device. In addition, when the crystal growth device is in use, the material properties of the preset object may also change with use, causing the first parameter to change. To this end, in order to more accurately determine the crystal face temperature during the crystal growth process, the parameter determination module 2610 may determine the first target parameter of the crystal growth device in the target heat cycle, i.e., the specific value of the first parameter in the target heat cycle, in various ways.

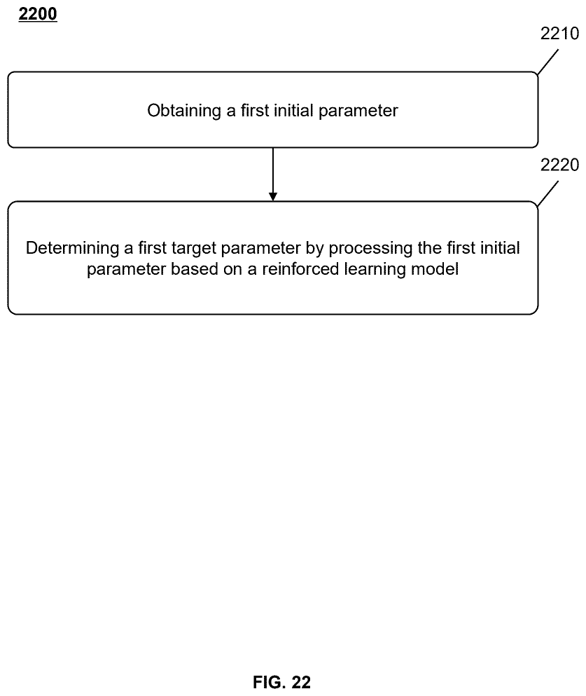

In some embodiments, the parameter determination module 2610 may obtain the first initial parameter, the first initial parameter reflecting a first parameter of the preset object in the crystal growth device in an initial environment; and determine the first target parameter by processing the first initial parameter based on a reinforced learning model, a reward value of the reinforced learning model being related to furnace information of the crystal growth device. More descriptions regarding the above embodiments may be found in FIG. 22 and related descriptions thereof.

In some embodiments, the parameter determination module 2610 may obtain a first correspondence relationship between a heat cycle of the crystal growth device and the first parameter; and determine the first target parameter based on the target heat cycle and the first correspondence relationship. More descriptions regarding the above embodiments may be found in FIG. 25 and related descriptions thereof.

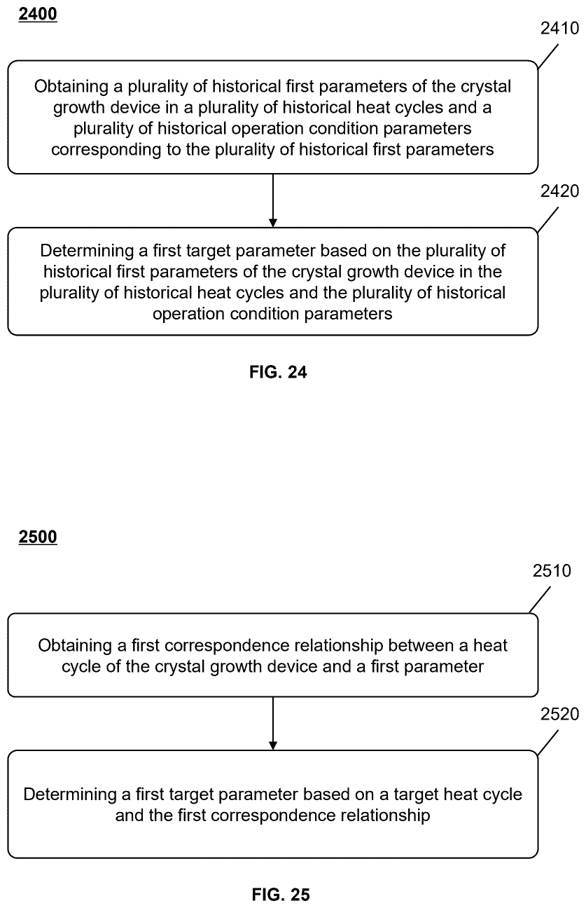

In some embodiments, the parameter determination module 2610 may obtain first historical parameters of the crystal growth device in a plurality of historical heat cycles and historical operation condition parameters corresponding to the first historical parameters, the first historical parameters reflecting the first parameter of the preset object in the crystal growth device in the plurality of historical heat cycles; and determine the first target parameter based on the first historical parameters of the plurality of historical heat cycles and the historical operation condition parameters. More descriptions regarding the above embodiments may be found in FIG. 24 and related descriptions thereof.

The second target parameter may include a second parameter of the crystal growth device in the target heat cycle. The second parameter may include a parameter related to the setting of the crystal growth device in the target heat cycle.

In some embodiments, the parameter determination module 2610 may determine a type of the second parameter by preset, and further determine a value of the second target parameter in the target heat cycle. The second parameter may include a heat cycle device parameter and a heat cycle growth parameter. The heat cycle device parameter may be a parameter related to the crystal growth device. For example, the heat cycle device parameter may include but is not limited to a count of top insulation layers, a distance between a top insulation bottom and a crucible top, a count of soft felts, a minimum inner diameter, a maximum outer diameter, a cover thickness, a material distance, an inner diameter of a gasket, a material height, a bottom insulation soft felt, an insulation inner tube hard felt, an insulation inner tube soft felt, an insulation outer tube hard felt, an insulation outer tube soft felt, an outermost layer of soft felt, a ring height, etc. The heat cycle growth parameter may be a parameter related crystal growth setting. For example, the heat cycle growth parameter may include a growth pressure, a growth power, a high temperature, a high temperature line, crystal growth time, a center thickness, an edge thickness, etc. Different heat cycles of the crystal growth device may cause different corresponding second parameters due to differences in the generated crystal type, crystal demand, etc.

In some embodiments, the second target parameter may be obtained by presetting the target heat cycle. For example, the second target parameter may be determined by a user (e.g., a manager of the crystal growth device) inputting the heat cycle device parameter and the heat cycle growth parameter of the target heat cycle. As another example, the heat cycle device parameter of the crystal growth device in the target heat cycle may be determined based on a preset type of the crystal growth device. As another example, the heat cycle growth parameter of the crystal growth device in the target heat cycle may be determined based on a preset crystal type, a preset crystal demand, etc.

In 2120, a first temperature measurement value of a first temperature measurement point of the crystal growth device may be obtained in a target time period of the target heat cycle. In some embodiments, the operation 2120 may be performed by a temperature measurement module 2620.

The target time period refers to a time period for measuring the temperature of the first temperature measurement point. The target time period may be preset by the user (e.g., an operator of the crystal growth device). The target heat cycle may include a plurality of time periods. The target time period may be a current time period.

The temperature measurement module 2620 may perform at least one temperature measurement within the target time period to obtain the first temperature measurement value of the first temperature measurement point of the crystal growth device. The temperature measurement module 2620 may be implemented by a temperature measurement device (e.g., the temperature measurement device 2020 shown in FIG. 20).

The first temperature measurement point is a temperature measurement point of the crystal growth device (e.g., in a furnace chamber of the crystal growth device). The first temperature measurement value is the temperature of the first temperature measurement point obtained by a measurement operation.

The crystal growth device may include one or more first temperature measurement points. The one or more first temperature measurement points may be preset by the user. The user may set the temperature measurement device at one or more positions. The temperature measurement module 2620 may obtain one or more first temperature measurement values of the one or more first temperature measurement points in the target time period of the target heat cycle by the temperature measurement device.

In 2130, a simulated crystal face temperature corresponding to the first temperature measurement value may be determined by a crystal face temperature determination model based on the at least one target parameter and the first temperature measurement value. In some embodiments, the operation 2130 may be performed by a temperature determination module 2630.

The simulated crystal face temperature refers to a crystal face temperature corresponding to the first temperature measurement value determined by simulation.

The crystal face temperature determination model may be a numerical value simulation model. The processor 2050 may establish a plurality of mathematical equations based on a plurality of historical target parameters of the plurality of historical heat cycles, first historical temperature measurement values, and historical crystal face temperatures, and discretize the plurality of mathematical equations to convert the plurality of mathematical equations into discrete mathematical equations for easy processing, and then solve the discretized mathematical equations using a numerical value calculation method, such as a finite difference method, a finite element method, etc., to obtain the crystal face temperature determination model. The temperature determination module 2630 may input the at least one target parameter and the first temperature measurement value into the crystal face temperature determination model. The crystal face temperature determination model may perform a simulation based on the input data to determine the simulated crystal face temperature.

Some embodiments of the present disclosure can determine the simulated crystal face temperature by simulation of the crystal face temperature determination model, to solve the problem that the crystal face temperature is difficult to observe.

In some embodiments, the crystal face temperature determination model may also be a machine learning model. For example, the crystal face temperature determination model may include but is not limited to a logistic regression model, a decision tree model, a stochastic gradient descent model, or the like, or any combination thereof. An input of the crystal face temperature determination model may include the at least one target parameter and the first temperature measurement value, and an output of the crystal face temperature determination model may include the simulated crystal face temperature corresponding to the first temperature measurement value. The crystal face temperature determination model may be obtained by obtaining an initial crystal face temperature determination model by modeling the crystal growth device by a numerical value simulation software (e.g., Virtual reactor, COMSOL, etc.) or a designed heat transfer calculation program and training the initial crystal face temperature determination model. A first training sample may include a sample target parameter and a sample first temperature measurement value. A first training label may include a sample crystal face temperature. The first training sample and the first training label may be obtained by performing heating experiments on the crystal growth device.

In some embodiments, the temperature determination module 2630 may determine the crystal face temperature determination model based on the type of the crystal growth device. The crystal face temperature determination model corresponding to each type of the crystal growth device may be obtained by training based on the first training sample and the first training label corresponding to each type of the crystal growth device.

In some embodiments, the input of the crystal face temperature determination model may further include position information of the first temperature measurement point. Correspondingly, the first training sample during training may further include sample position information of the first sample temperature measurement point. By using the position information of the first temperature measurement point as the input of the crystal face temperature determination model, the error caused by a position difference of the first temperature measurement point can be avoided, and the accuracy of the output of the crystal face temperature determination model can be improved.

In some embodiments, the crystal face temperature determination model may further include a numerical value simulation model and a machine learning model. For example, the temperature determination module 2630 may process the at least one target parameter and the first temperature measurement value based on the numerical value simulation model and the machine learning model, and perform weighted summation on results output by the numerical value simulation model and the machine learning model, and determine a result of the weighted summation as the simulated crystal face temperature. The numerical value simulation model and the machine learning model may be obtained by preset. The numerical value simulation model may be usually affected by uncertainties from different sources, such as model parameter uncertainty, noise in input data, etc. The machine learning model may be applied to estimation and modeling uncertainty to provide more accurate prediction results and effective uncertainty quantification. By combining the output results of the numerical value simulation model and the machine learning model, a more accurate simulated crystal face temperature can be obtained.

According to some embodiments of the present disclosure, the parameter set of the crystal growth device in the target heat cycle can be determined more accurately, so as to more accurately determine the crystal face temperature during the crystal growth process and improve the crystal growth quality. In addition, by determining the crystal face temperature using the crystal face temperature determination model, the determination efficiency can be improved, and the cost of manual determination can be reduced.

In some embodiments, after the simulated crystal face temperature is determined, the process 2100 may also determine a temperature control parameter for adjusting the temperature of the crystal growth device in the target time period. Optionally, the process 2100 may also include the following operations.

In 2140, a temperature control parameter of the crystal growth device in the target time period of the target heat cycle may be determined based on the simulated crystal face temperature. In some embodiments, the operation 2140 may be performed by a temperature control module 2640.

The temperature control parameter is a parameter of the crystal growth device for adjusting the temperature in the furnace chamber. The temperature control parameter may include a power of the furnace chamber in the crystal growth device. For example, the temperature control parameter may be +5 KW, indicating that the current power of the furnace chamber needs to be increased by 5 KW in the target time period. The temperature control parameter may also include an adjustment value of a furnace temperature in the crystal growth device. For example, the temperature control parameter may be +2000° C., indicating that the current furnace temperature needs to be increased by 2000° C. in the target time period.

In some embodiments, the temperature control module 2640 may feed back the simulated crystal face temperature to the operator of the target heat cycle. The operator may determine the temperature control parameter of the crystal growth device in the target time period of the target heat cycle according to the simulated crystal face temperature.

In some embodiments, the temperature control module 2640 may determine the temperature control parameter of the crystal growth device in the target time period of the target heat cycle based on crystal growth information of the target heat cycle and the simulated crystal face temperature by a temperature control relationship. The crystal growth information refers to relevant information of crystal growth of the target heat cycle. For example, the crystal growth information may include but is not limited to a crystal type, a current crystal growth situation (e.g., a size), a current crystal growth duration, a target growth duration, etc. The target growth duration refers to an estimated duration required for crystal growth in the target heat cycle. The crystal growth information may be directly input by the user, or may be obtained in real-time during the crystal growth process. For example, the crystal type, the target growth duration, etc. may be directly determined by the user input. As another example, the current crystal growth situation (e.g., a crystal size) and the current crystal growth duration may be obtained in real-time during the crystal growth process.

The temperature control module 2640 may determine a crystal face temperature required by the crystal in the target time period according to the crystal growth information, and determine the temperature control parameter of the crystal growth device in the target time period based on the simulated crystal face temperature and a preset temperature control relationship. More descriptions regarding the temperature control relationship may be found in the related descriptions of the present disclosure below.

The temperature control module 2640 may obtain a plurality of reference crystal face temperatures of each of a plurality of reference devices in reference heat cycles and a plurality of reference control parameters corresponding to the plurality of reference crystal face temperatures. The plurality of reference devices are devices of the same type as the crystal growth device. The reference heat cycles are crystal growth heat cycles performed by the plurality of reference devices. The plurality of reference crystal face temperatures refer to crystal face temperatures of the plurality of reference devices in the reference heat cycles. The plurality of reference crystal face temperatures may be a temperature sequence, characterizing different crystal face temperatures of the plurality of reference devices in a plurality of time periods of the reference heat cycles. The plurality of reference control parameters refer to temperature control parameters of the plurality of reference devices in the reference heat cycles. The plurality of reference control parameters may be a temperature control parameter sequence, characterizing different temperature control parameters of the plurality of reference devices in a plurality of time periods of the reference heat cycles.

In some embodiments, the temperature control module 2640 may determine the temperature control parameter based on the plurality of reference crystal face temperatures of the plurality of reference devices in the reference heat cycles, the plurality of reference control parameters, and the simulated crystal face temperature.

For example, the temperature control module 2640 may determine at least one reference heat cycle based on the simulated crystal face temperature and the plurality of reference crystal face temperatures, and then determine the temperature control parameter of the crystal growth device in the target time period of the target heat cycle based on a reference control parameter corresponding to the at least one reference heat cycle. When there is one reference heat cycle, the temperature control module 2640 may directly determine a reference control parameter corresponding to the reference heat cycle as the temperature control parameter of the crystal growth device in the target time period of the target heat cycle. It can be understood that in different reference heat cycles, the reference control parameter corresponding to the same reference crystal face temperature may be different. Therefore, when there are a plurality of reference heat cycles, the temperature control module 2640 may comprehensively evaluate the reference control parameters of the plurality of reference heat cycles to determine the temperature control parameter of the crystal growth device in the target time period of the target heat cycle. For example, an average value or a median value of the reference control parameters corresponding to the plurality of reference heat cycles may be determined, and the average value or the median value may be determined as the temperature control parameter of the crystal growth device in the target time period of the target heat cycle.

For example, the temperature control module 2640 may determine the temperature control relationship between the temperature control parameter of the crystal growth device and the crystal face temperature based on the plurality of reference crystal face temperatures of the plurality of reference devices in the reference heat cycles and the plurality of reference control parameters. The temperature control relationship may characterize the effect of the adjustment of the temperature control parameter on the crystal face temperature.

In some embodiments, the temperature control relationship may be characterized by a temperature control model. An input of the temperature control model may include a simulated crystal face temperature from the start of crystal growth to the target time period, and an output of the temperature control model may include a temperature control parameter from the target time period to the completion of crystal growth.

The temperature control model may be obtained by training based on the plurality of reference crystal face temperatures of the plurality of reference devices in the reference heat cycles and the plurality of reference control parameters. The temperature control module 2640 may block or remove a part of crystal face temperatures of a portion of time periods from the plurality of reference crystal face temperatures to obtain second training samples. Second training labels may include reference control parameters corresponding to the remaining time periods. The temperature control module 2640 may train an initial temperature control model based on the second training samples and the second training labels to obtain the temperature control model.

The temperature control module 2640 may determine a crystal face temperature required by the crystal growth device in the target time period of the target heat cycle based on the crystal growth information of the target heat cycle, and determine the temperature control parameter of the crystal growth device in the target time period of the target heat cycle by the temperature control relationship based on the crystal face temperature required by the crystal growth device in the target time period of the target heat cycle and the simulated crystal face temperature, to make the grown crystal meet the requirements.

The temperature control module 2640 may obtain crystal detection data of the crystal generated by the plurality of reference devices in the reference heat cycles. The crystal detection data refers to relevant detection data of the crystal. For example, the crystal detection data may include but is not limited to a crystal size, a crystal quantity, the presence of the crystal or not, etc.

In some embodiments, the temperature control module 2640 may determine the temperature control parameter based on the plurality of reference crystal face temperatures of the plurality of reference devices in the reference heat cycles, the plurality of reference control parameters, the crystal detection data, and the simulated crystal face temperature. The temperature control module 2640 may screen the plurality of reference crystal face temperatures of the plurality of reference devices in the reference heat cycles and the plurality of reference control parameters based on the crystal growth information of the target heat cycle and the crystal detection data of the plurality of reference devices in the reference heat cycles to obtain reference crystal face temperatures and reference control parameters after screening, and determine the temperature control parameter of the crystal growth device in the target time period of the target heat cycle based on the reference crystal face temperatures and the reference control parameters after screening and the simulated crystal face temperature. For example, the temperature control module 2640 may only retain reference crystal face temperatures and reference control parameters corresponding to reference heat cycles of which a crystal size in the crystal detection data is equal to or greater than a preset size threshold. By screening the reference heat cycles of the plurality of reference devices according to the crystal detection data, data that does not meet the requirements can be screened out, to make that the temperature control parameter of the target heat cycle in the target time period is more in line with the requirements of the crystal growth information.

It should be noted that if the simulated crystal face temperature is only fed back to the operator as a reference, the operator is still required to set the temperature of a crystal growth furnace based on experience, which makes the monitoring of the crystal face temperature still not comprehensive enough and cannot ensure that the crystal face temperature during the crystal growth process is constant, thus reducing the crystal growth quality. According to some embodiments of the present disclosure, the temperature control parameter is determined by the temperature control module 2640, which can make the determined temperature control parameter more suitable for crystal growth, realize automatic control, reduce labor costs, and reduce the operation error rate.

In some embodiments, the crystal growth system 2600 may adjust a crystal growth temperature of the crystal growth device in the target time period based on the temperature control parameter. Optionally, the process 2100 may further include the following operations.

In 2150, a temperature adjustment instruction may be automatically sent based on the temperature control parameter to adjust a crystal growth temperature of the crystal growth device in the target time period of the target heat cycle. In some embodiments, the operation 2150 may be performed by a temperature adjustment module 2650.

The temperature adjustment instruction is a control instruction for components of the crystal growth device to adjust the temperature. The temperature adjustment module 2650 may generate a temperature adjustment instruction based on the temperature control parameter, and send the temperature adjustment instruction to a corresponding component of the crystal growth device to adjust the crystal growth temperature of the crystal growth device in the target time period of the target heat cycle, such that the crystal growth temperature meets the requirements of crystal growth, thereby improving the crystal growth quality.

For example, when the temperature control parameter includes the power of the furnace chamber of the crystal growth device being +5 KW, the temperature adjustment module 2650 may convert the temperature control parameter into a corresponding temperature adjustment instruction. The temperature adjustment instruction may be sent to the furnace chamber. The furnace chamber may increase the current power by 5 KW in response to the temperature adjustment instruction.

According to some embodiments of the present disclosure, the temperature adjustment of the crystal growth device can be automatically controlled by the temperature control parameter, thereby realizing intelligent control of crystal growth, and reducing the cost caused by manual operation.

It should be noted that, in the target heat cycle of the crystal growth device, the crystal growth system 2600 may continuously perform the process 2100 to determine the crystal face temperature in each time period, thereby realizing intelligent control of the crystal growth device based on the crystal face temperature, and improving the crystal growth quality.

It should be noted that the above description of the process 2100 is merely provided for the purposes of illustration, and not intended to limit the scope of the present disclosure. For persons having ordinary skills in the art, multiple variations and modifications can be made to the process 2100 under the teachings of the present disclosure However, those variations and modifications do not depart from the scope of the present disclosure. For example, the crystal growth system 2600 may first perform operation 2120 and then perform operation 2110 to achieve the crystal growth method described in the embodiments of the present disclosure.

FIG. 22 is a flowchart illustrating an exemplary process for determining a first parameter according to some embodiments of the present disclosure. In some embodiments, process 300 may be performed by the parameter determination module 2610. As shown in FIG. 22, process 300 may include the following operations. In 2210, a first initial parameter may be obtained.

The first initial parameter may reflect a first parameter of a preset object in a crystal growth device in an initial environment. The initial environment may refer to an environment when the manufacturer of the crystal growth device measures the first parameter of the preset object. At this time, the crystal growth device has not performed crystal growth. One or more of a temperature, a magnetic field, an electric field, or the like, of the initial environment may be determined by preset. The first initial parameter may be determined by device information of the crystal growth device. For example, when producing the crystal growth device the manufacturer of the crystal growth device may test the preset object in the initial environment (e.g., the temperature is 20-30° C., and the magnetic field is 1-2 milligauss) to determine the first parameter of the preset object under the initial environment.

It can be understood that as the crystal is generated, the environment in which the preset object is located changes relative to the initial environment (e.g., the temperature in the initial environment is 20-30° C., and the temperature during crystal growth is 7400-7500° C.). In addition, as the crystal growth device is used, an internal structure of the preset object may also change, which in turn causes the first parameter of the preset object in the crystal growth device to change continuously.

In 2220, a first target parameter may be determined by processing the first initial parameter based on a reinforced learning model.

For each first initial parameter, the parameter determination module 2610 may input the first initial parameter into the reinforced learning model. An output of the reinforced learning model may be a corresponding first target parameter. A reward value of the reinforced learning model may be related to the furnace information of the crystal growth device. The furnace information may be relevant information of the crystal growth device during the crystal growth process, including but not limited to the furnace temperature, furnace pressure, exhaust rate, etc. The furnace information may be determined in various ways. The furnace information may be determined based on detection. For example, the parameter determination module 2610 may detect by a relative detection device to obtain the furnace information. The furnace information may also be determined based on calculation. For example, the parameter determination module 2610 may determine the furnace temperature based on the first temperature measurement value by a preset temperature correspondence relationship between the preset furnace temperature and the first temperature measurement value. As another example, the parameter determination module 2610 may determine the furnace temperature by calculation based on the target heat cycle and the power of the crystal growth device.

The reinforced learning model may be configured to modify the first initial parameter to obtain a modified first target parameter. A reinforced learning model 2320 may include an adjustment module 2321 and an optimal action determination module 2322.

As shown in FIG. 23, the parameter determination module 2610 may input a first initial parameter 2310 into the reinforced learning model 2320, and an output of the reinforced learning model 2320 may be a first target parameter 2330. In the reinforced learning model 2320, the first initial parameter 2310 may be input into the adjustment module 2321, and the adjustment module 2321 may output an optional action set. Then the first initial parameter 2310 and the optional action set may be input into the optimal action determination module 2322. The optimal action determination module 2322 may output an optimal optional action 2323. The parameter determination module 2610 may use a value corresponding to the optimal optional action 2323 output by the optimal action determination module 2322 as the output of the reinforced learning model 2320, i.e., the first target parameter 2330.

The adjustment module 2321 may include an optional action determination submodule 2321-1, a state determination submodule 2321-2, and a reward determination submodule 2321-3. In a prediction process of the reinforced learning model 2320, the adjustment module 2321 may determine the optional action set by the optional action determination submodule 2321-1 based on the first initial parameter 2310. It should be noted that the first target parameter 2330 finally determined by adjusting the first initial parameter 2310 based on the optional action set should not exceed a correction range of the first initial parameter 2310. The correction range refers to a range for correcting the first initial parameter. It is understood that since the type of each first initial parameter is different, the correction range corresponding to each first initial parameter may be different. The correction range may be preset based on experience.

During a training process of the reinforced learning model 2320, the state determination submodule 2321-2 and the reward determination submodule 2321-3 of the adjustment module 2321 may be configured to determine a first parameter of the next state and the reward value, respectively.

The optional action determination submodule 2321-1 may determine an optional action set in a current state based on a first parameter (e.g., during initial execution, the first parameter of the current state may be the first initial parameter 2310) of the current state. The optional action set refers to a set of actions that can be executed for the first parameter of the current state in a certain state. It should be noted that the adjusted first parameter should not exceed the correction range corresponding to the first initial parameter.

The state determination submodule 2321-2 may be configured to determine the first parameter of the next state based on the first parameter of the current state and the optimal optional action 2323 output by the optimal action determination module 2322.

The reward determination submodule 2321-3 may be configured to determine the reward value. The reward value may be configured to determine the accuracy of the adjusted first parameter. For example, for an action with high accuracy, the reward value may be higher; for an action with low accuracy or negative improvement, the reward value may be lower. The reward value may be expressed as a numerical value or in other ways. In some embodiments, the reward value of the reinforced learning model may be related to the furnace information of the crystal growth device. Taking the first parameter as electrical conductivity and the furnace information as the furnace temperature as an example, the parameter determination module 2610 may input the adjusted first parameter into a simulation model. An output of the simulation model may be a simulation temperature of the crystal growth device corresponding to the current adjusted first parameter. The simulation temperature may be compared with the furnace temperature of the crystal growth device to determine the reward value of the adjusted first parameter. The reward value may be determined based on a temperature difference between the simulation temperature and the furnace temperature of the crystal growth device and a preset reward rule. The smaller the temperature difference, the greater the reward value. The simulation model may be obtained by training with historical data of the crystal growth device.

The optimal action determination module 2322 may be configured to determine the optimal optional action 2323 based on the first parameter of the current state and the optional action set. In some embodiments, the optimal action determination module 2322 may be a machine learning model, which may be implemented in various ways, such as a deep neural network (DNN), a convolutional neural network (CNN), a recurrent neural network (RNN), etc.

In some embodiments, the optimal action determination module 2322 may be obtained by training based on a plurality sets of third training sample with third training label according to a reinforced learning method, such as a deep Q-Learning Network (DQN), a double deep Q-Learning Network (DDQN), etc. The third training sample may include a historical first parameter of the crystal growth device. The third training label may include an optimal optional action corresponding to the historical first parameter. The third training sample may be obtained based on the historical data of the crystal growth device. The third training label may be obtained by the reinforced learning method.

In some embodiments, the parameter determination module 2610 may periodically execute the reinforced learning model 2320 to output the optimal optional action 2323 based on a preset trigger condition. For example, the preset trigger condition may be executing the reinforced learning model 2320 once every heat cycle, and the parameter determination module 2610 may determine the optimal optional action 2323 output by the reinforced learning model 2320 in the target heat cycle as the first target parameter of the target heat cycle.

According to some embodiments of the present disclosure, the first initial parameter is processed by the reinforced learning model, so as to more accurately determine the first target parameter, and improve the accuracy of the determined simulated crystal face temperature.

FIG. 24 is a flowchart illustrating an exemplary process for determining a first target parameter according to some embodiments of the present disclosure. In some embodiments, process 2400 may be performed by the parameter determination module 2610. As shown in FIG. 24, process 2400 may include the following operations.

In 2410, a plurality of historical first parameters of the crystal growth device in a plurality of historical heat cycles and a plurality of historical operation condition parameters corresponding to the plurality of historical first parameters may be obtained.

The plurality of historical heat cycles refer to heat cycles of crystal growth performed by the crystal growth device before a target heat cycle. Correspondingly, the plurality of historical first parameters refer to a plurality of first parameters of the crystal growth device in the plurality of historical heat cycles.

The plurality of historical operation condition parameters refer to a plurality of parameters related to operation condition of the crystal growth device in the plurality of historical heat cycles.

In some embodiments, the plurality of historical operation condition parameters may include second temperature measurement values of second temperature measurement points of the crystal growth device in the plurality of historical heat cycles. The second temperature measurement points refer to positions where the crystal growth device measures the temperature in the furnace in the plurality of historical heat cycles. The second temperature measurement values refer to results obtained by the crystal growth device detecting the temperature at the second temperature measurement points in the plurality of historical heat cycles. The second temperature measurement points may be the same as or different from the position of the first temperature measurement point.

In some embodiments, the plurality of historical operation condition parameters may include historical growth durations of crystal growth in the crystal growth device in the plurality of historical heat cycles. The historical growth durations refer to durations for crystal growth taken by the crystal growing equipment (e.g., the crystal growth device) in the plurality of historical heat cycles.

In some embodiments, the plurality of historical operation condition parameters may include other parameters. For example, the plurality of historical operation condition parameters may include but are not limited to furnace power, furnace pressure, exhaust rate, or the like of the plurality of historical heat cycles.

The parameter determination module 2610 may obtain the plurality of historical first parameters of the crystal growth device in the plurality of historical heat cycles and the plurality of historical operation condition parameters corresponding to the plurality of historical first parameters based on the historical data of the crystal growth device. For example, the crystal growth device may further include a storage module. The crystal growth device may detect relevant data each time the crystal growth device performs crystal growth. For example, the crystal growth device may detect the historical first parameters and the historical operation condition parameters, and store the historical first parameters and the historical operation condition parameters in the storage module as the historical data. The parameter determination module 2610 may obtain the plurality of historical first parameters of the crystal growth device in the plurality of historical heat cycles and the plurality of historical operation condition parameters corresponding to the plurality of historical first parameters from the storage module when necessary.

In 2420, the first target parameter may be determined based on the plurality of historical first parameters of the crystal growth device in the plurality of historical heat cycles and the plurality of historical operation condition parameters.

In some embodiments, when the plurality of historical operation condition parameters include the second temperature measurement values of the second temperature measuring points of the crystal growth device in the plurality of historical heat cycles, the parameter determination module 2610 may analyze and process the historical first parameters and the second temperature measurement values of the plurality of historical heat cycles to determine a second correspondence relationship between the temperature measurement value of the second temperature measurement point and the first parameter. The second correspondence relationship may reflect a correspondence relationship between the temperature measurement value of the second temperature measurement point of the crystal growth device and the first parameter. The second correspondence relationship may be characterized as a fitting function, a machine learning model, etc. It can be understood that when the first parameter includes multiple types, the second correspondence relationship may include a correspondence relationship between each type of the first parameter and the temperature measurement value of the second temperature measuring point. For example, when the first parameter includes the thermal conductivity and electrical conductivity of a crucible, the second correspondence relationship may include a correspondence relationship between the temperature measurement value of the second temperature measurement point and the thermal conductivity and a correspondence relationship between the temperature measurement value of the second temperature measurement point and the electrical conductivity of the crucible.

In some embodiments, the parameter determination module 2610 may obtain a third temperature measurement value of the second temperature measurement point of the crystal growth device in the target heat cycle, and determine the first parameter based on the third temperature measurement value and the second correspondence relationship. The third temperature measurement value refers to a result obtained by the crystal growth device performing temperature measurement on the second temperature measurement point in the target heat cycle. It can be understood that when the first temperature measurement point is the same as the second temperature measurement point, the third temperature measurement value is the first temperature measurement value. The parameter determination module 2610 may determine the first parameter corresponding to the third temperature measurement value based on the second correspondence relationship, and determine the first parameter as the first target parameter.

In some embodiments, when the plurality of historical operation condition parameters include the historical growth durations of the crystal growth device in the plurality of historical heat cycles, the parameter determination module 2610 may determine a third correspondence relationship based on the plurality of historical first parameters of the plurality of historical heat cycles and the plurality of historical growth durations. The third correspondence relationship may reflect a third correspondence relationship between the crystal growth duration and the first parameter. The third correspondence relationship may be characterized as a fitting function, a machine learning model, etc. Similar to the second correspondence relationship, when the first parameter includes multiple types, the third correspondence relationship may include a correspondence relationship between each type of the first parameter and the crystal growth duration.

In some embodiments, the parameter determination module 2610 may obtain a target growth duration of the crystal growth device in the target heat cycle for crystal growth; and determine the first parameter based on the target crystal growth duration and the third correspondence relationship. The parameter determination module 2610 may determine the first parameter corresponding to the target growth duration based on the third correspondence relationship, and determine the first parameter as the first target parameter.

In some embodiments, the parameter determination module 2610 may establish a parameter prediction model based on the plurality of historical first parameters and the plurality of historical operation condition parameters of the plurality of historical heat cycles; determine a preset operation condition parameter of the crystal growth device in the target heat cycle; and determine the first target parameter based on the preset operation condition parameter and the parameter prediction model.

The preset operation condition parameter refers to a preset operation condition parameter in the target heat cycle. The preset operation condition parameter may include but is not limited to a preset furnace temperature, a preset furnace pressure, a preset exhaust rate, a preset furnace power, or the like of the crystal growth device in each time period of the target heat cycle. The parameter determination module 2610 or a user may plan a growth situation of the target heat cycle based on crystal growth information to determine the preset operation condition parameter of the crystal growth device in the target heat cycle. More descriptions regarding the crystal growth information may be found in FIG. 21 and the related descriptions thereof.

In some embodiments, the parameter determination module 2610 may input the preset operation condition parameter of the target heat cycle into the parameter prediction model. An output of the parameter prediction model may include a first parameter under the preset operation condition parameter. The parameter determination module 2610 may determine the first parameter under the preset operation condition parameter as the target parameter. The parameter prediction model may be a machine learning model. For example, the parameter prediction model may include but is not limited to one of a convolutional neural network model, a deep learning model, and a random forest model, or any combination thereof. According to some embodiments of the present disclosure, the first parameter can be quickly and accurately determined by the parameter prediction model, so as to improve the processing efficiency.

The parameter determination module 2610 may train an initial parameter prediction model based on a plurality sets of fourth training sample with fourth training label to obtain a trained parameter prediction model. For each set of fourth training sample with the fourth training label, the fourth training sample may include a historical operation condition parameter of a certain historical heat cycle, and the fourth training label may include a historical first parameter corresponding to the historical heat cycle.

According to some embodiments of the present disclosure, the first parameter can be determined by analyzing and processing the plurality of historical first parameters and the plurality of historical operation condition parameters of the plurality of historical heat cycles of the crystal growth device, such that the first parameter of the crystal growth device in the target heat cycle can be more accurately determined, and errors in determining the crystal face temperature caused by directly determining the first parameter based on the first initial parameter can be avoided.

FIG. 25 is a flowchart illustrating another exemplary process for determining a first target parameter according to some embodiments of the present disclosure. In some embodiments, process 2500 may be performed by the parameter determination module 2610. As shown in FIG. 25, process 2500 may include the following operations.

In 2510, a first correspondence relationship between the heat cycle of the crystal growth device and the first parameter may be obtained.

In some embodiments, for each of a plurality of preset heat cycles of the crystal growth device, the parameter determination module 2610 may process the first initial parameter based on a reinforced learning model to determine a reference first parameter corresponding to each preset heat cycle. The plurality of preset heat cycles may refer to a plurality of heat cycles preset by the crystal growth device. For example, the plurality of preset heat cycles may be the first 20 heat cycles of the crystal growth device. The reference first parameter is the first parameter of the crystal growth device in the preset heat cycle. More descriptions regarding the reinforced learning model may be found in FIG. 22 and the related descriptions thereof.

The parameter determination module 2610 may determine the first correspondence relationship between the heat cycle of the crystal growth device and the first parameter based on the reference first parameters corresponding to the plurality of preset heat cycles. Similar to the second correspondence relationship and the third correspondence relationship, the first correspondence relationship may be characterized by a fitting function or a machine learning model. For example, the parameter determination module 2610 may perform data fitting on the reference first parameters corresponding to the plurality of preset heat cycles to determine a fitting function between the heat cycle of the crystal growth device and the first parameter and determine the fitting function as the first correspondence relationship. As another example, the parameter determination module 2610 may determine the plurality of preset heat cycles as fifth training samples, determine the reference first parameters corresponding to the plurality of preset heat cycles as fifth training labels, perform training based on the fifth training samples and the fifth training labels, determine a machine learning model, and determine the machine learning model as the first correspondence relationship.

In 2520, the first target parameter may be determined based on the target heat cycle and the first correspondence relationship.

For example, when the first correspondence relationship is the fitting function, the parameter determination module 2610 may determine the first target parameter by calculation based on the target heat cycle. As another example, when the first correspondence is the machine learning model, the parameter determination module 2610 may input the target heat cycle into the machine learning model, and an output of the machine learning model may be the first target parameter.

According to some embodiments of the present disclosure, the first target parameter may be determined by the first correspondence relationship, such that the amount of calculation caused by processing continuously based on the reinforced learning model can be avoided, and the calculation efficiency of the crystal growth system 2600 can be improved while ensuring the accuracy of the first target parameter.

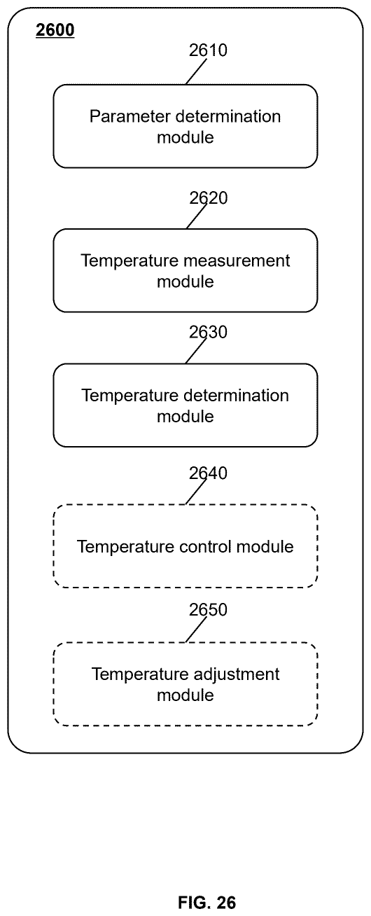

FIG. 26 is a block diagram illustrating an exemplary crystal growth system according to some embodiments of the present disclosure.

As shown in FIG. 26, the crystal growth system 2600 may include the parameter determination module 2610, the temperature measurement module 2620, and the temperature determination module 2630.

The parameter determination module 2610 may be configured to determine the parameter set of the crystal growth device in the target heat cycle. The parameter set may include at least one target parameter. The at least one target parameter may be a parameter of the crystal growth device that affects crystal growth. In some embodiments, the at least one target parameter may include the first target parameter and the second target parameter. The first target parameter may include the first parameter of a preset object in the crystal growth device in the target heat cycle. The first parameter may reflect a material physical property related to crystal growth of the preset object. The second target parameter may include a second parameter of the crystal growth device in the target heat cycle. The second parameter may include a parameter related to the setting of the crystal growth device.

In some embodiments, the parameter determination module 2610 may be further configured to obtain the first initial parameter. The first initial parameter may reflect the first parameter of the preset object in the crystal growth device in an initial environment. The first initial parameter may be processed based on a reinforced learning model to determine the first target parameter. A reward value of the reinforced learning model may be related to the furnace information of the crystal growth device.

In some embodiments, the parameter determination module 2610 may be further configured to obtain the first correspondence relationship between the heat cycle of the crystal growth device and the first parameter; and determine the first target parameter based on the target heat cycle and the first correspondence relationship.

In some embodiments, the parameter determination module 2610 may be further configured to process the first initial parameter based on the reinforced learning model for each of the plurality of preset heat cycles of the crystal growth device to determine the reference first parameter corresponding to the preset heat cycle, the first initial parameter reflecting the first parameter of the preset object in the crystal growth device in the initial environment, and the reference first parameter being the first parameter of the crystal growth device in the preset heat cycle, and the reward value of the reinforced learning model being related to the furnace information of the crystal growth device; and determine the first correspondence relationship between the heat cycle of the crystal growth device and the first parameter based on the reference first parameter corresponding to the preset heat cycle.

In some embodiments, the parameter determination module 2610 may be further configured to obtain the historical first parameters of the crystal growth device in the plurality of historical heat cycles and the historical operation parameters corresponding to the historical first parameters, the historical first parameters reflecting the first parameters of the preset object in the crystal growth device in the historical heat cycles; and determine the first target parameter based on the historical first parameters of the plurality of historical heat cycles and the historical operation condition parameters. In some embodiments, the historical operation condition parameters may include second temperature measurement values of the second temperature measurement point of the crystal growth device in the plurality of historical heat cycles. The parameter determination module 2610 may be further configured to determine the second correspondence relationship based on the historical first parameters of the plurality of historical heat cycles and the second temperature measurement values, the second correspondence relationship reflecting a correspondence relationship between the temperature measurement value of the second temperature measurement point of the crystal growth device and the first parameter; obtain the third temperature measurement value of the second temperature measurement point of the crystal growth device in the target heat cycle; and determine the first target parameter based on the third temperature measurement value and the second correspondence relationship. In some embodiments, the historical operation condition parameters may include historical growth durations of the crystal growth device in the plurality of historical heat cycles. The parameter determination module 2610 may be further configured to determine the third correspondence relationship based on the historical first parameters and the historical growth durations of the plurality of historical heat cycles, the third correspondence relationship reflecting a correspondence relationship between the crystal growth duration and the first parameter; obtain a target crystal growth duration of the crystal growth device in the target heat cycle; and determine the first target parameter based on the target growth duration and the third correspondence relationship. In some embodiments, the parameter determination module 2610 may be further configured to establish a parameter prediction model based on the historical first parameters and the historical operation condition parameters of the plurality of historical heat cycles; determine a preset operation condition parameter of the crystal growth device in the target heat cycle; and determine the first target parameter based on the preset operation condition parameter and the parameter prediction model.

In some embodiments, the parameter determination module 2610 may be further configured to obtain a plurality sets of reference data, each set of the plurality sets of reference data including the plurality of first candidate parameters and verification information corresponding to the plurality of first candidate parameters, and each of the plurality of first candidate parameters reflecting a material physical property of the preset object in the crystal growth device; and determine types of the first parameters by processing the plurality sets of the reference data by an importance analysis model, the importance analysis model being a random forest model.

The temperature measurement module 2620 may be configured to obtain the first temperature measurement value of the first temperature measurement point of the crystal growth device during the target time period of the target heat cycle.

The temperature determination module 2630 may be configured to determine a simulated crystal face temperature corresponding to the first temperature measurement value by a crystal face temperature determination model based on the at least one target parameter and the first temperature measurement value.

In some embodiments, the crystal growth system 2600 shown in FIG. 26 may further include a temperature control module 2640. The temperature control module 2640 may be configured to determine the temperature control parameter of the crystal growth device in the target time period of the target heat cycle based on the simulated crystal face temperature. In some embodiments, the temperature control module 2640 may be further configured to obtain a plurality of reference crystal face temperatures of each of a plurality of reference devices in reference heat cycles and a plurality of reference control parameters corresponding to the plurality of reference crystal face temperatures, the plurality of reference devices being devices of the same type as the crystal growth device; and determine the temperature control parameter based on the plurality of reference crystal face temperatures of the plurality of reference devices in the reference heat cycles, the plurality of reference control parameters, and the simulated crystal face temperature. In some embodiments, the temperature control module 2640 may be further configured to obtain crystal detection data of crystals generated by the plurality of reference devices in the reference heat cycles; and determine the temperature control parameter based on the plurality of reference crystal face temperatures of the plurality of reference devices in the reference heat cycles, the plurality of reference control parameters, the crystal detection data, and the simulated crystal face temperature.

In some embodiments, the crystal growth system 2600 shown in FIG. 26 may further include the temperature adjustment module 2650. The temperature adjustment module 2650 may be configured to automatically send a temperature adjustment instruction based on the temperature control parameter to adjust the crystal growth temperature of the crystal growth device in the target time period of the target heat cycle.

It should be understood that the crystal growth system 2600 and the modules thereof shown in FIG. 26 may be implemented in various ways. For example, the crystal growth system 2600 may be applied to a processor of a crystal growth apparatus. The crystal growth apparatus may also include the crystal growth device. The processor may be configured to control the crystal growth device by the crystal growth system 2600 to implement the crystal growth method described in any embodiment of the present disclosure.

It should be noted that the above description of the crystal growth system 2600 and the modules thereof is merely provided for the purposes of illustration, and not intended to limit the scope of the present disclosure. It should be understood that for those skilled in the art, after understanding the principle of the system, it may be possible to arbitrarily combine various modules, or form a subsystem to connect with other modules without departing from the principle. In some embodiments, the parameter determination module 2610, the temperature measurement module 2620, and the temperature determination module 2630 disclosed in FIG. 26 may be different modules in the system, or a single module which can implement the functions of two or more modules mentioned above. For example, modules in the crystal growth system 2600 can share a storage module, or each module may have its own storage module. Such variations are all within the scope of protection of the present disclosure.

The possible beneficial effects of the embodiments of the present disclosure may include but not be limited to the following:
(1) An actual crystal parameter may be obtained during a crystal growth process in real time. A temperature control parameter and a pulling control parameter may be adjusted according to a difference between the actual crystal parameter and a reference crystal parameter. Therefore, the crystal growth process may be controlled accurately and the quality of a prepared crystal may be improved.
(2) By dividing the crystal growth control process into a plurality of time slices and performing a gradual control among the time slices, the crystal growth process may be controlled accurately and the actual crystal may be consistent with a crystal growth model.
(3) By continuously detecting a weight of a seed crystal during a process of dropping the seed crystal and detecting a crystal weight during an automatic ending operation and controlling a pulling component to move in a reverse direction, the collision and adhesion between the seed crystal and a chamber may be effectively avoided, and a stability of the crystal growth control process may be improved.

It should be noted that different embodiments may have different beneficial effects. In different embodiments, possible beneficial effects may be any of the above effects, any combination thereof, or any other beneficial effects that may be obtained.

The above content describes this disclosure and/or some other examples. Based on the above content, this disclosure may also be modified in different ways. The subject matter disclosed in this disclosure can be implemented in different forms and examples, and this disclosure can be applied to a large number of applications. All applications, modifications and changes claimed in the following claims belong to the scope of this disclosure.

Moreover, certain terminology has been used to describe embodiments of the present disclosure. For example, the terms “one embodiment,” “an embodiment,” and/or “some embodiments” mean that a particular feature, structure or characteristic described in connection with the embodiment is included in at least one embodiment of the present disclosure. Therefore, it is emphasized and should be appreciated that two or more references to “an embodiment,” “one embodiment,” or “an alternative embodiment” in various portions of this specification are not necessarily all referring to the same embodiment. In addition, certain features, structures, or characteristics in one or more embodiments of the present disclosure may be appropriately combined.

Those skilled in the art may understand that the content disclosed in the present disclosure may have many variations and improvements. For example, the different system components described above may all be realized by hardware devices, but they may also be realized only by software solutions. For example, the system may be installed on an existing server. In addition, location information disclosed herein may be provided through a firmware, a combination of firmware/software, a combination of firmware/hardware, or a combination of hardware/firmware/software.

All software or part of the software may sometimes communicate through a network, such as the Internet or other communication networks. This type of communication may load software from one computer device or processor to another. For example, a hardware platform may be loaded from a management server or host computer of a crystal growth control system to a computer environment, or other computer environment for realizing the system. Therefore, another medium that can transmit software elements may also be used as a physical connection between local devices, such as light waves, electric waves, electromagnetic waves, etc., through cables, optical cables, or air. The physical medium used for carrier waves, such as cables, wireless connections, or optical cables, may also be considered as the medium that carry software. Unless the usage herein limits the tangible “storage” medium, other terms referring to the computer or machine “readable medium” all refer to the medium that participates in the process of executing any instructions by the processor.

Computer program code for carrying out operations for aspects of the present disclosure may be written in any combination of one or more programming languages, including an object oriented programming language such as Java, Scala, Smalltalk, Eiffel, JADE, Emerald, C++, C#, VB. NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (e.g., through the Internet using an Internet Service Provider) or in a cloud computing environment or offered as a service such as a Software as a Service (SaaS).

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installing on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure method does not mean that the present disclosure object requires more features than the features mentioned in the claims. Rather, claimed subject matter may lie in less than all features of a single foregoing disclosed embodiment.

In some embodiments, numbers expressing quantities of ingredients, properties, and so forth, used to describe and claim certain embodiments of the application are to be understood as being modified in some instances by the term “about,” “approximate,” or “substantially”. Unless otherwise stated, “about,” “approximate,” or “substantially” may indicate ±20% variation of the value it describes. Accordingly, in some embodiments, the numerical parameters set forth in the description and attached claims are approximations that may vary depending upon the desired properties sought to be obtained by a particular embodiment. In some embodiments, the numerical parameters should be construed in light of a count of reported significant digits and by applying ordinary rounding techniques. Notwithstanding that the numerical ranges and parameters configured to illustrate the broad scope of some embodiments of the present disclosure are approximations, the numerical values in specific examples may be as accurate as possible within a practical scope.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, or any of same that may have a limiting affect as to the broadest scope of the claims now or later associated with the present document. It should be noted that if the description, definition, and/or terms used in the appended application of the present disclosure is inconsistent or conflicting with the content described in the present disclosure, the use of the description, definition and/or terms of the present disclosure shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present disclosure are not limited to that precisely as shown and described.

What is claimed is:

1. A method for controlling crystal growth, comprising:
obtaining a crystal parameter in a target time slice continuously during an automatic ending operation, the crystal parameter including a crystal mass;
determining whether the crystal mass is greater than a first preset threshold or a first difference of the crystal mass between a current moment and a previous moment is greater than a first preset difference threshold;
determining that a crystal is bonded to a wall of a chamber in response to determining that the crystal mass is greater than the first preset threshold or the difference is greater than the first preset difference threshold; and
controlling a pulling component to move in a reverse direction.

2. The method of claim 1, wherein the first preset threshold is greater than a crystal weight of the crystal after the crystal is completely separated from a raw material liquid.

3. The method of claim 1, wherein the first preset difference threshold is a maximum weight that a crystal can increase between adjacent moments.

4. The method of claim 1, wherein the controlling a pulling component to move in a reverse direction comprises:
controlling the pulling component to move in the reverse direction until the crystal mass is less than the first preset threshold; and
the method further comprises:
controlling the pulling component to pull the crystal upward.

5. The method of claim 1, further comprising:
determining the crystal mass is greater than the first preset threshold again;
controlling the pulling component to move in the reverse direction again; and
repeating several times until the crystal mass is continuously less than the first preset threshold.

6. The method of claim 1, further comprising:
providing a first prompt in response to determining that the crystal mass is greater than the first preset threshold or the difference is greater than the first preset difference threshold.

7. The method of claim 1, further comprising:
obtaining the crystal parameter in a target time slice continuously during an automatic seed crystal dropping process, the crystal parameter including a crystal mass of a seed crystal;
determining whether the crystal mass of the seed crystal is less than a second preset threshold or a second difference of the crystal mass of the seed crystal between a current moment and a previous moment is greater than a second preset difference threshold;
determining that the seed crystal hits the wall of the chamber in response to determining that the crystal mass of the seed crystal is less than the second preset threshold or the second difference is greater than the second preset difference threshold, and
stopping dropping the seed crystal.

8. The method of claim 7, further comprising:
providing a second prompt in response to determining that the crystal mass of the seed crystal is less than the second preset threshold or the second difference is greater than the second preset difference threshold.

9. The method of claim 7, wherein the second preset threshold is a minimum weight of the seed crystal after the seed crystal contacts a liquid level of a raw material liquid and is melted.

10. The method of claim 7, wherein the second preset difference threshold is a maximum weight that the seed crystal can reduce between adjacent moments.

11. The method of claim 7, wherein the second preset threshold is 0.8 times or 0.7 times an initial weight of the seed crystal.

12. The method of claim 7, wherein the second preset difference threshold is 1 gram or 2 grams.

13. The method of claim 1, further comprising:
determining a parameter set of a crystal growth device in a target heat cycle, wherein the parameter set includes at least one target parameter and the at least one target parameter is a parameter of the crystal growth device that affects crystal growth;
obtaining a first temperature measurement value of a first temperature measurement point of the crystal growth device in a target time period of the target heat cycle; and
determining, based on the at least one target parameter and the first temperature measurement value, a simulated crystal face temperature corresponding to the first temperature measurement value by a crystal face temperature determination model.

14. The method of claim 13, further comprising:
determining a temperature control parameter of the crystal growth device in the target time period of the target heat cycle based on the simulated crystal face temperature; and
automatically sending a temperature adjustment instruction, based on the temperature control parameter, to adjust a crystal growth temperature of the crystal growth device in the target time period of the target heat cycle.

15. The method of claim 13, wherein the at least one target parameter includes a first target parameter and a second target parameter,
the first target parameter includes a first parameter of a preset object in the crystal growth device in the target heat cycle, the first parameter reflecting a material physical property of the preset object related to crystal growth,
the second target parameter includes a second parameter of the crystal growth device in the target heat cycle, the second parameter including a parameter related to setting of the crystal growth device.

16. The method of claim 15, wherein the material physical property includes at least one of thermal conductivity, electrical conductivity, surface emissivity, a heat transfer coefficient, an isobaric heat capacity, and relative magnetic permeability, and the preset object includes at least one of a crucible, a thermal insulation felt, a raw material melt, and a protective gas.

17. The method of claim 15, wherein the determining a parameter set of a crystal growth device in a target heat cycle comprises:
obtaining a first initial parameter, the first initial parameter reflecting the first parameter of the preset object in the crystal growth device in an initial environment; and
determining the first target parameter by processing the first initial parameter based on a reinforced learning model, a reward value of the reinforced learning model being related to heat cycle information of the crystal growth device.

18. The method of claim 15, wherein the determining a parameter set of a crystal growth device in a target heat cycle comprises:
obtaining a first correspondence relationship between a heat cycle of the crystal growth device and the first parameter; and
determining the first target parameter based on the target heat cycle and the first correspondence relationship.

19. A system for controlling crystal growth, applied to a crystal preparation process, wherein the system comprises:
at least one storage storing computer instructions;
at least one processor in communication with the at least one storage, when executing the computer instructions, the at least one processor causes the system to:
obtain a crystal parameter in a target time slice continuously during an automatic ending operation, the crystal parameter including a crystal mass;
determine whether the crystal mass is greater than a first preset threshold or a first difference of the crystal mass between a current moment and a previous moment is greater than a first preset difference threshold;
determine that a crystal is bonded to a wall of a chamber in response to determining that the crystal mass is greater than the first preset threshold or the difference is greater than the first preset difference threshold, and
control a pulling component to move in a reverse direction.

20. A computer-readable storage medium, wherein the storage medium stores computer instructions, the instructions, when executed by at least one processor, causing the at least one processor to perform operations including:
obtaining a crystal parameter in a target time slice continuously during an automatic ending operation, the crystal parameter including a crystal mass;
determining whether the crystal mass is greater than a first preset threshold or a first difference of the crystal mass between a current moment and a previous moment is greater than a first preset difference threshold;
determining that a crystal is bonded to a wall of a chamber in response to determining that the crystal mass is greater than the first preset threshold or the difference is greater than the first preset difference threshold, and
controlling a pulling component to move in a reverse direction.
